(19) United States
(12) Patent Application Publication
(10) Pub. No.: US 2022/0285383 A1
(43) Pub. Date: Sep. 8, 2022

(54) SEMICONDUCTOR MEMORY DEVICE

(71) Applicant: Kioxia Corporation, Tokyo (JP)

(72) Inventors: Yoshihiro KUBOTA, Yokkaichi (JP); Taichi IWASAKI, Yokkaichi (JP)

(73) Assignee: Kioxia Corporation, Tokyo (JP)

(21) Appl. No.: 17/444,075

(22) Filed: Jul. 30, 2021

(30) Foreign Application Priority Data
Mar. 8, 2021 (JP) 2021-036304

(51) Int. Cl. H01L 27/11573; H01L 27/02; H01L 27/11556; H01L 27/11529; H01L 27/11582

(52) U.S. Cl. CPC H01L 27/11573; H01L 27/0255; H01L 27/11556; H01L 27/11529; H01L 27/11582

(57) ABSTRACT

A semiconductor memory device according to an embodiment includes a substrate, a source line, a plurality of word lines, a pillar, and a first contact portion. The word lines are spaced apart from each other in a first direction. A bottom portion of the pillar reaches the source line. The first contact portion is provided on the substrate. The first contact portion is connected between the source line and the substrate. An inside of the first contact portion, or a portion in which a conductive layer included in the source line is in contact with the first contact portion, includes a portion functioning as a diode. The portion functioning as the diode is electrically connected in a reverse direction from the source line toward the substrate.

### CROSS-REFERENCE TO RELATED APPLICATIONS

This application is based upon and claims the benefit of priority from Japanese Patent Application No. 2021-036304, filed Mar. 8, 2021, the entire contents of which are incorporated herein by reference.

### FIELD Embodiments described herein relate generally to a semiconductor memory device.

### BACKGROUND

There is known a NAND-type flash memory capable of storing data in a nonvolatile manner.

### BRIEF DESCRIPTION OF THE DRAWINGS

FIG. 1 is a block diagram illustrating an example of an overall configuration of a semiconductor memory device according to a first embodiment;

FIG. 2 is a circuit diagram illustrating an example of a circuit configuration of a memory cell array included in the semiconductor memory device according to the first embodiment;

FIG. 3 is a plan view illustrating an example of a plan layout of the semiconductor memory device according to the first embodiment;

FIG. 4 is a plan view illustrating an example of a plan layout in a core region of the semiconductor memory device according to the first embodiment;

FIG. 5 is a plan view illustrating an example of a plan layout in a memory region of the semiconductor memory device according to the first embodiment;

FIG. 6 is a cross-sectional view taken along a line VI-VI of FIG. 5, FIG. 6 illustrating an example of cross-sectional structure in the memory region of the semiconductor memory device according to the first embodiment;

FIG. 7 is a cross-sectional view taken along a line VII-VII of FIG. 6, FIG. 7 illustrating an example of cross-sectional structure of a memory pillar in the semiconductor memory device according to the first embodiment;

FIG. 8 is a plan view illustrating an example of a plan layout in a hookup region and a contact region of the semiconductor memory device according to the first embodiment;

FIG. 9 is a cross-sectional view taken along a line IX-IX of FIG. 8, FIG. 9 illustrating an example of cross-sectional structure in the hookup region and the contact region of the semiconductor memory device according to the first embodiment;

FIG. 10 is a plan view illustrating an example of a plan layout in a wiring layer including a source line of the semiconductor memory device according to the first embodiment;

FIG. 11 is a cross-sectional view taken along a line XI-XI of FIG. 10, FIG. 11 illustrating an example of cross-sectional structure in the memory region, the contact region and a wall region of the semiconductor memory device according to the first embodiment;

FIG. 12 is a cross-sectional view illustrating an example of cross-sectional structure including a discharge-path contact portion and a contact portion of the semiconductor memory device according to the first embodiment;

FIG. 13 is a flowchart illustrating an example of a method for manufacturing the semiconductor memory device according to the first embodiment;

FIGS. 14, 15, 16, 17, 18, 19 and 20 are cross-sectional views illustrating an example of cross-sectional structure during manufacturing of the semiconductor memory device according to the first embodiment;

FIG. 21 is a flowchart illustrating an example of a method for manufacturing the semiconductor memory device according to the first embodiment;

FIGS. 22, 23, 24, 25, 26, 27, 28, 29, 30, 31 and 32 are cross-sectional views illustrating an example of cross-sectional structure during manufacturing of the semiconductor memory device according to the first embodiment;

FIG. 33 is a cross-sectional view illustrating an example of cross-sectional structure during manufacturing of the semiconductor memory device according to the first embodiment;

FIG. 34 is a cross-sectional view illustrating an example of cross-sectional structure including a discharge-path contact portion of a semiconductor memory device according to a first modification of the first embodiment;

FIG. 35 is a cross-sectional view illustrating an example of cross-sectional structure including a discharge-path contact portion of a semiconductor memory device according to a second modification of the first embodiment;

FIG. 36 is a plan view illustrating an example of a plan layout in a wiring layer including a source line of a semiconductor memory device according to a second embodiment;

FIG. 37 is a plan view illustrating an example of a plan layout of a bridge portion in the semiconductor memory device according to the second embodiment;

FIG. 38 is a cross-sectional view taken along a line XXXVIII-XXXVIII of FIG. 36, FIG. 38 illustrating an example of cross-sectional structure in the memory region, the contact region and the wall region of the semiconductor memory device according to the second embodiment;

FIG. 39 is a flowchart illustrating an example of a method for manufacturing the semiconductor memory device according to the second embodiment;

FIGS. 40, 41, 42, 43, 44, 45, 46, 47 and 48 are cross-sectional views illustrating an example of cross-sectional structure during manufacturing of the semiconductor memory device according to the second embodiment;

FIG. 49 is a cross-sectional view illustrating an example of cross-sectional structure during manufacturing of the semiconductor memory device according to the second embodiment;

FIG. 50 is a plan view illustrating an example of a plan layout of a bridge portion in a semiconductor memory device according to a first modification of the second embodiment;

FIG. 51 is a cross-sectional view taken along a line LI-LI of FIG. 50, FIG. 51 illustrating an example of cross-sectional structure of a discharge-path contact portion in the semiconductor memory device according to the first modification of the second embodiment;

FIG. 52 is a cross-sectional view illustrating an example of cross-sectional structure of a discharge-path contact portion in a semiconductor memory device according to a second modification of the second embodiment;

FIG. 53 is a cross-sectional view illustrating an example of cross-sectional structure of a discharge-path contact portion in a semiconductor memory device according to a third modification of the second embodiment; and

FIG. 54 is a cross-sectional view illustrating an example of cross-sectional structure of a discharge-path contact portion in a semiconductor memory device according to a fourth modification of the second embodiment.

### DETAILED DESCRIPTION

In general, according to one embodiment, a semiconductor memory device includes a substrate, a source line, a plurality of word lines, a pillar, and a first contact portion. The source line is provided above the substrate. The word lines are provided above the source line. The word lines are spaced apart from each other in a first direction intersecting a surface of the substrate. The pillar is provided to extend in the first direction. A bottom portion of the pillar reaches the source line. Each of intersection portions between the pillar and the word lines functions as a memory cell. The first contact portion is provided on the substrate. The first contact portion is connected between the source line and the substrate. An inside of the first contact portion, or a portion in which a conductive layer included in the source line is in contact with the first contact portion, includes a portion functioning as a diode. The portion functioning as the diode is electrically connected in a reverse direction from the source line toward the substrate.

Hereinafter, embodiments will be described with reference to the drawings. Each embodiment exemplifies a device or method for embodying a technical idea of the invention. The drawings are schematic or conceptual, and the dimensions and ratios of each drawing are not always the same as the actual ones. The technical idea of the present invention is not specified by the shape, structure, arrangement, and the like of constituent elements.

Note that, in the following description, constituent elements having substantially the same functions and configurations are denoted by the same signs. A number after a character constituting a reference sign is used for distinguishing between elements that are referred to by a reference sign including the same character and have similar configurations. When it is not necessary to distinguish between elements indicated by a reference sign including the same character, each of these elements is referred to by the reference sign including only the character.

### [1] First Embodiment

Hereinafter, a semiconductor memory device 1 according to a first embodiment will be described.

### [1-1] Configuration of Semiconductor Memory Device 1

### [1-1-1] Overall Configuration of Semiconductor Memory Device 1

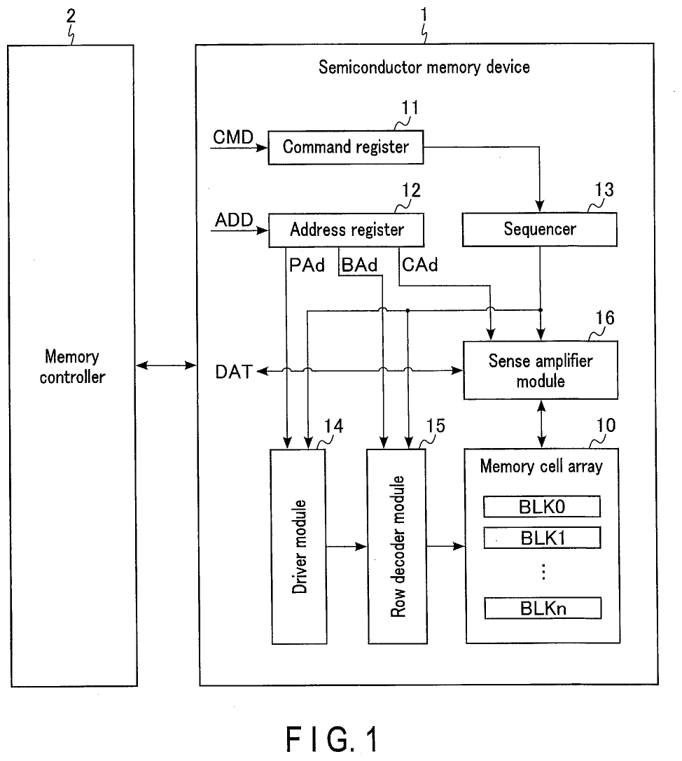

FIG. 1 is a block diagram illustrating a configuration example of the semiconductor memory device 1 according to the first embodiment. The semiconductor memory device 1 is a NAND-type flash memory capable of storing data in a nonvolatile manner, and can be controlled by an external memory controller 2. As illustrated in FIG. 1, the semiconductor memory device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer of 1 or more). Each block BLK is a set of a plurality of memory cells capable of storing data in a nonvolatile manner, and is used, for example, as a unit of data erasure. Furthermore, the memory cell array 10 is provided with a plurality of bit lines and a plurality of word lines. Each memory cell is associated with, for example, one bit line and one word line. A detailed configuration of the memory cell array 10 will be described later.

The command register 11 holds a command CMD received by the semiconductor memory device 1 from the memory controller 2. The command CMD includes, for example, an instruction to cause the sequencer 13 to execute a read operation, a write operation, an erase operation, and the like.

The address register 12 holds address information ADD received by the semiconductor memory device 1 from the memory controller 2. The address information ADD includes, for example, a block address BAd, a page address PAd, and a column address CAd. For example, the block address BAd, the page address PAd, and the column address CAd are used for selecting the block BLK, word line, and bit line, respectively.

The sequencer 13 controls the operation of the entire semiconductor memory device 1. For example, the sequencer 13 controls the driver module 14, the row decoder module 15, the sense amplifier module 16, and the like, based on the command CMD held in the command register 11, and executes the read operation, the write operation, the erase operation, and the like.

The driver module 14 generates a voltage used in the read operation, the write operation, the erase operation, or the like. In addition, the driver module 14 applies a generated voltage to a signal line corresponding to a selected word line, based on, for example, the page address PAd held in the address register 12.

The row decoder module 15 selects a corresponding one block BLK in the memory cell array 10, based on the block address BAd held in the address register 12. Then, the row decoder module 15 transfers, for example, the voltage applied to the signal line corresponding to the selected word line to the selected word line in the selected block BLK.

In the write operation, the sense amplifier module 16 applies a desired voltage to each bit line, depending on write data DAT received from the memory controller 2. Furthermore, in the read operation, the sense amplifier module 16 determines data stored in the memory cell, based on the voltage of the bit line, and reads and transfers a determination result as read data DAT to the memory controller 2.

The semiconductor memory device 1 and the memory controller 2 described above may constitute one semiconductor device by a combination thereof. Examples of such a semiconductor device include a memory card such as an SDTM card, a solid state drive (SSD), and the like.

### [1-1-2] Circuit Configuration of Memory Cell Array 10

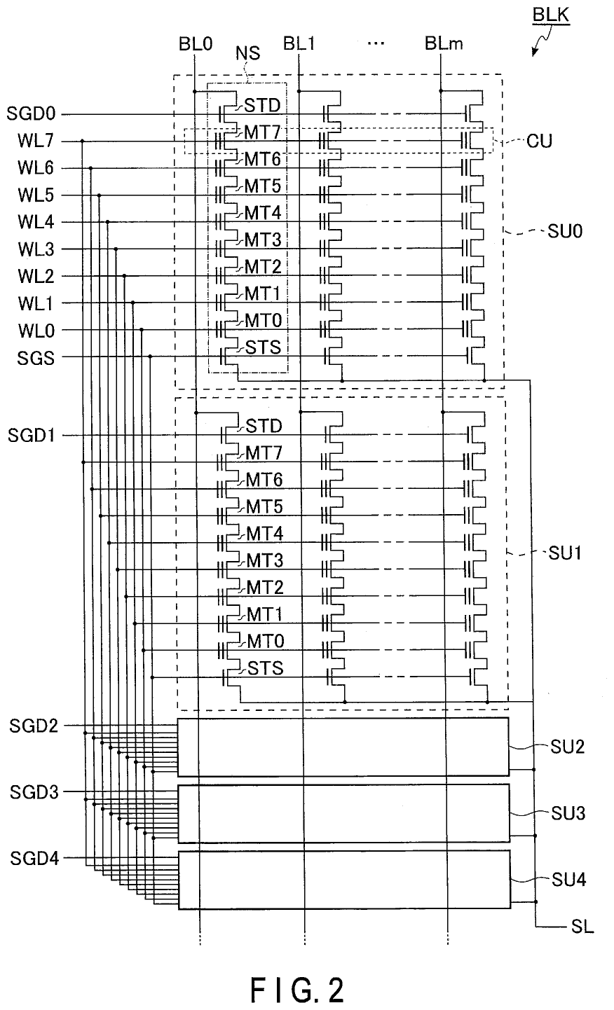

FIG. 2 is a circuit diagram illustrating an example of a circuit configuration of the memory cell array 10 included in the semiconductor memory device 1 according to the first embodiment. FIG. 2 illustrates one block BLK of the blocks BLK included in the memory cell array 10. As illustrated in FIG. 2, the block BLK includes, for example, five string units SU0 to SU4.

Each string unit SU includes a plurality of NAND strings NS which are associated with bit lines BL0 to BLm (m is an integer of 1 or more), respectively. Each. NAND string NS includes, for example, memory cell transistors MT0 to MT7, and select transistors STD and STS. Each memory cell transistor MT includes a control gate and a charge storage layer, and holds data in a nonvolatile manner. Each of the select transistors STD and STS is used for selecting the string unit SU during various operations.

In each NAND string NS, the memory cell transistors MT0 to MT7 are connected in series. The drain of the select transistor STD is connected to each bit line BL associated. The source of the select transistor STD is connected to one end of the memory cell transistors MT0 to MT7 connected together in series. The drain of the select transistor STS is connected to the other end of the memory cell transistors MT0 to MT7 connected in series. The source of the select transistor STS is connected to a source line SL.

In the same block BLK, the control gates of the memory cell transistors MT0 to MT7 are connected to the word lines WL0 to WL7, respectively. The gates of the select transistors STD in the string unit SU0 are connected to a select gate line SGD0. The gates of the select transistors STD in the string unit SU1 are connected to a select gate line SGD1. The gates of the select transistors STD in the string unit SU2 are connected to a select gate line SGD2. The gates of the select transistors STD in the string unit SU3 are connected to a select gate line SGD3. The gates of the select transistors STD in the string unit SU4 are connected to a select gate line SGD4. The gates of the select transistors STS are connected to a select gate line SGS.

Different column addresses are assigned to the bit lines BL0 to BLm, respectively. Each bit line BL is shared by the NAND strings NS to which the same column address is assigned among the blocks BLK. Each of the word lines WL0 to WL7 is provided for each block BLK. The source line SL is shared among the blocks BLK, for example.

A set of the memory cell transistors MT connected to a common word line WL in one string unit SU is referred to as, for example, a cell unit CU. For example, a storage capacity of the cell unit CU including the memory cell transistors MT each storing 1-bit data is defined as “1 page data”. The cell unit CU can have a storage capacity of 2 page data or more, depending on the number of bits of data stored in the memory cell transistor MT.

Note that, the circuit configuration of the memory cell array 10 included in the semiconductor memory device 1 according to the first embodiment is not limited to the configuration described above. For example, the number of string units SU included in each block BLK, the number of memory cell transistors MT included in each NAND string NS, and the number of select transistors STD and. STS included in each NAND string NS, may be freely selected.

[1-1-3] Structure of Memory Cell Array 10

Hereinafter, an example will be described of structure of the memory cell array 10 included in the semiconductor memory device 1 according to the embodiment. Note that, in the drawings referred to below, an X direction corresponds to an extending direction of the word line WL, a Y direction corresponds to an extending direction of the bit line BL, and a Z direction corresponds to the vertical direction with respect to a surface of a semiconductor substrate 20 used for formation of the semiconductor memory device 1. In the plan view, hatching is appropriately added to make it easier to see the figure. The hatching added to the plan view is not necessarily related to a material and characteristics of a constituent element to which the hatching is added. In the cross-sectional view, illustration of the configuration is appropriately omitted to make it easier to see the figure.

(Plan Layout of Semiconductor Memory Device 1)

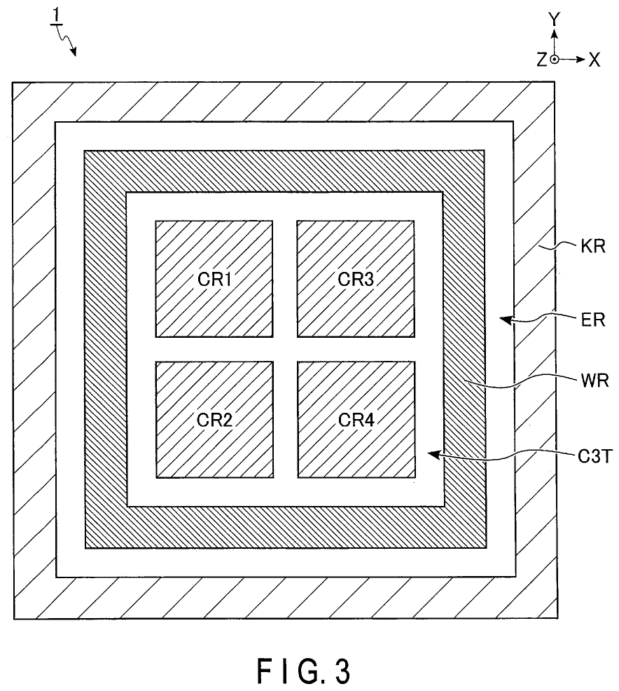

FIG. 3 is a plan view illustrating an example of a plan layout of the semiconductor memory device 1 according to the first embodiment. As illustrated in FIG. 3, the plan layout of the semiconductor memory device 1 is divided into, for example, core regions CR1, CR2, CR3 and CR4, a wall region WR, a kerf region KR, a contact region C3T, and an end region ER.

Each of the core regions CR1, CR2, CR3 and CR4 is, for example, a rectangular region provided in a central portion of the semiconductor substrate 20. The core regions CR1, CR2, CR3 and CR4 are arranged, for example, in a matrix. Specifically, the core regions CR1 and CR2 neighbor each other in the Y direction. The core regions CR3 and CR4 neighbor each other in the Y direction. The core regions CR1 and CR2 neighbor the core regions CR3 and CR4 in the X direction. The memory cell array 10 is arranged in each core region CR. The shape and the number of core regions CR can be freely designed. It suffices that each core region CR is, at least, surrounded by the wall region WR.

The wall region WR is a square ring region provided to surround the outer periphery of the core regions CR1 to CR4. Sealing members ESn and ESp to be described later are arranged in the wall region WR. The wall region WR may be provided to collectively surround the core regions CR, or may be provided for each core region CR. Peripheral circuits such as the row decoder module 15 and sense amplifier module 16 are arranged in a region surrounded by the wall region WR. Note that the peripheral circuits include portions arranged to overlap the memory cell array 10 in the Z direction.

The contact region C3T is a region which is surrounded by the wall region WR and excludes the core regions CR1 to CR4. In the contact region C3T, for example, a contact is arranged for connecting the memory cell array 10 to the peripheral circuits. For example, the row decoder module 15 is electrically connected to a wiring line (the word line WL or the like) in the memory cell array 10 via the contact provided in the contact region C3T.

The kerf region KR is a square ring region provided to surround the outer periphery of the wall region WR, and is in contact with the outermost periphery of the semiconductor substrate 20. The kerf region KR is provided with, for example, an alignment mark used during manufacturing of the semiconductor memory device 1, a guard ring, and the like. A structure in the kerf region KR may be removed by a dicing process of cutting a plurality of the semiconductor memory devices 1 formed on a wafer into chips.

The end region ER is a region between the kerf region KR and the wall region WR. The kerf region KR and the wall region WR are spaced apart via the end region ER.

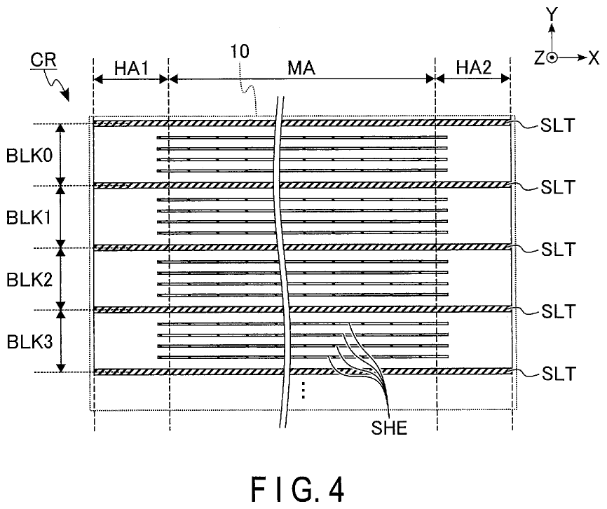

FIG. 4 is a plan view illustrating an example of a plan layout in the core region CR of the semiconductor memory device 1 according to the first embodiment. FIG. 4 illustrates regions corresponding to four blocks BLK0 to BLK3 included in the memory cell array 10. As illustrated in FIG. 4, the core region CR is divided into a memory region MA and hookup regions HA1 and HA2 in the X direction, for example. In addition, the memory cell array 10 includes a plurality of slits SLT and SHE.

The memory region MA includes the NAND strings NS. The memory region MA is sandwiched in the X direction by the hookup regions HA1 and HA2. Each of the hookup regionsHA1 and HA2 is a region used for connection between stacked wiring lines (for example, the word lines WL and the select gate lines SGD and SGS) and the row decoder module 15.

The slits SLT include portions extending in the X direction, and are arranged in the Y direction. Each slit SLT crosses the memory region MA and the hookup regionsHA1 and HA2 in the X direction. Furthermore, each slit SLT has, for example, such a structure that an insulator or a plate-shaped contact is buried. In addition, each slit SLT divides wiring lines (for example, the word lines WL0 to WL7 and the select gate lines SGD and SGS) neighboring each other via the slit SLT.

The slits SHE include portions extending in the X direction, and are arranged in the Y direction. In this example, four slits SHE are arranged in each of spaces between adjacent slits SLT. Each slit SHE crosses the memory region MA in the X direction, and one end of each slit SHE is included in the hookup region HA1 and the other end is included in the hookup region HA2. Furthermore, each slit SHE has, for example, such a structure that an insulator is buried. In addition, each slit SHE divides wiring lines (at least, the select gate line SGD) neighboring each other via the slit SHE.

In the plan layout of the memory cell array 10 described above, each of regions separated by the slits SLT corresponds to one block BLK. Furthermore, each of regions separated by the slits SLT and SHE corresponds to one string unit SU. In addition, in the memory cell array 10, for example, the layout illustrated in FIG. 4 is repeatedly arranged in the Y direction.

Note that the plan layout of the memory cell array 10 included in the semiconductor memory device 1 according to the first embodiment is not limited to the layout described above. For example, the number of slits SHE arranged between mutually neighboring slits SLT can freely be designed. The number of string units SU formed between mutually neighboring slits SLT can be changed based on the number of slits SHE arranged between the mutually neighboring slits SLT.

(Structure of Semiconductor Memory Device 1 in Memory Region MA)

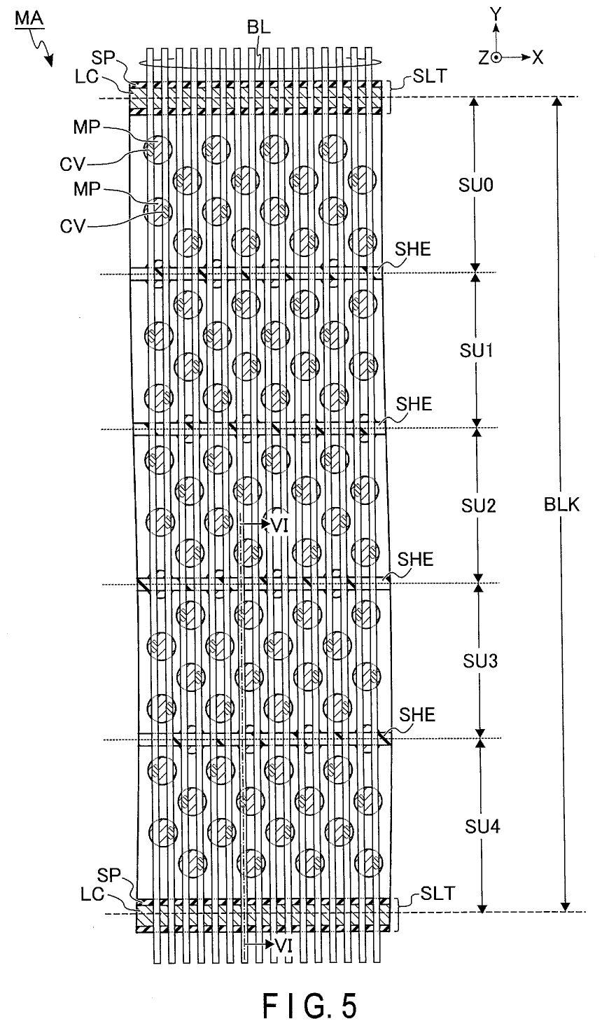

FIG. 5 is a plan view illustrating an example of a plan layout in the memory region MA of the semiconductor memory device 1 according to the first embodiment. FIG. 5 illustrates a region including one block BLK (i.e. the string units SU0 to SU4). As illustrated in FIG. 5, the semiconductor memory device 1 further includes, for example, a plurality of memory pillars MP, a plurality of contacts CV, and a plurality of bit lines BL in the memory region MA. Furthermore, each slit SLT includes a contact LC and spacers SP.

Each of the memory pillars MP functions, for example, as one NAND string NS. The memory pillars MP are arranged in a staggered pattern of, for example, 24 rows in a region between two adjacent slits SLT. In addition, for example, counting from the upper side of the drawing sheet, each of the memory pillar MP in the fifth row, the memory pillar MP in the tenth row, the memory pillar MP in the 15th row, and the memory pillar MP in the 20th row overlaps one slit SHE.

The bit lines BL include portions extending in the Y direction, and are arranged in the X direction. Each bit line BL is arranged to overlap at least one memory pillar MP for each string unit SU. In this example, two bit lines BL are arranged to overlap one memory pillar MP. One bit line BL of the bit lines BL overlapping the memory pillar MP, and the memory pillar MP are electrically connected via the contact CV.

For example, the contact CV is omitted between the memory pillar MP, which is in contact with the slit SHE, and the bit line BL. In other words, the contact CV is omitted between the memory pillar MP, which is in contact with two different select gate lines SGD, and the bit line BL. The number and arrangement of the memory pillars MP, the slits SHE, and the like between the adjacent slits SLT are not limited to the configuration described with reference to FIG. 5, and can be changed as appropriate. The number of bit lines BL overlapping each memory pillar MP can be designed to be any number.

The contact LC is a conductor having a portion provided to extend in the X direction. The spacers SP are insulators provided on side surfaces of the contact LC. The contact LC is sandwiched by the spacers SP. The contact LC is separated and insulated by the spacers SP from conductors (e.g. the word lines WL0 to WL7, and the select gate lines SGD and SGS) adjacent to the contact LC in the Y direction. The spacer SP is, for example, an oxide film.

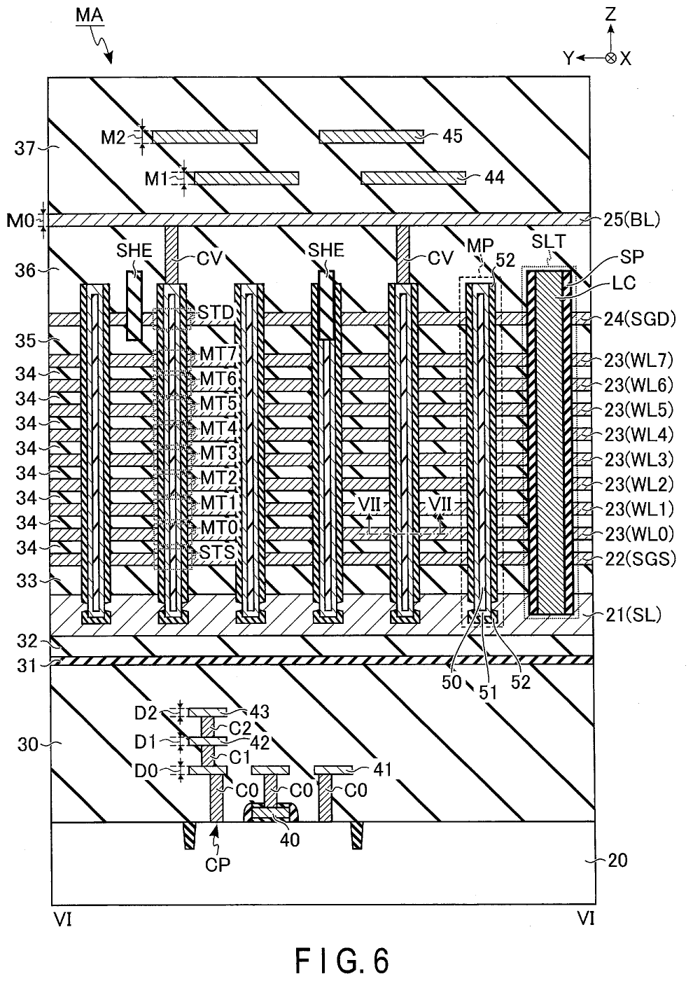

FIG. 6 is a cross-sectional view taken along a line VI-VI of FIG. 5, FIG. 6 illustrating an example of cross-sectional structure in the memory region MA of the semiconductor memory device 1 according to the first embodiment. As illustrated in FIG. 6, the semiconductor memory device 1 further includes, for example, the semiconductor substrate 20, conductive layers 21 to 25, and insulating layers 30 to 37 in the memory region MA. Hereinafter, details will be described of the structure of the semiconductor memory device 1 in the memory region MA.

The semiconductor substrate 20 is, for example, a P-type semiconductor substrate. The insulating layer 30 is provided on the semiconductor substrate 20. The insulating layer 30 includes a circuit corresponding to the row decoder module 15, the sense amplifier module 16, and the like. For example, the insulating layer 30 can include conductive layers 40 to 43 and contacts C0 to C2. The conductive layer 40 is provided on the semiconductor substrate 20 via a gate insulating film. The conductive layer 40 functions as a gate electrode of a transistor provided under the memory cell array 10. A plurality of the contacts C0 are provided on each of the conductive layer 40 and the semiconductor substrate 20. The contact C0 provided on the semiconductor substrate 20 is connected to an impurity diffusion region (not illustrated) provided on the semiconductor substrate 20. The conductive layer 41 is provided on the contact C0. The contact C1 is provided on the conductive layer 41. The conductive layer 42 is provided on the contact C1. The contact C2 is provided on the conductive layer 42. The conductive layer 43 is provided on the contact C2.

The insulating layer 31 is provided on the insulating layer 30. The insulating layer 31 contains, for example, silicon nitride. The insulating layer 31 prevents hydrogen, which is generated in, for example, a thermal process for forming a stacked structure of the memory cell array 10, from entering a transistor provided on the semiconductor substrate 20. The insulating layer 31 may be referred to as a barrier film.

The insulating layer 32 is provided on the insulating layer 31. The conductive layer 21 is provided on the insulating layer 32. The conductive layer 21 is formed in a plate shape extending along the XY plane, for example, and is used as the source line SL. The conductive layer 21 contains, for example, phosphorus-doped silicon.

The insulating layer 33 is provided on the conductive layer 21. The conductive layer 22 is provided on the insulating layer 33. The conductive layer 22 is formed in a plate shape extending along the XY plane, for example, and is used as the select gate line SGS. The conductive layer 22 contains, for example, tungsten.

The insulating layers 34 and the conductive layers 23 are alternately stacked on the conductive layer 22. The conductive layer 23 is formed in a plate shape extending along the XY plane, for example. The stacked conductive layers 23 are used as word lines WL0 to WL7 in the named order from the semiconductor substrate 20 side. The conductive layer 23 contains, for example, tungsten.

The insulating layer 35 is provided on the uppermost conductive layer 23. The conductive layer 24 is provided on the insulating layer 35. The conductive layer 24 is formed in a plate shape extending along the XY plane, for example, and is used as the select gate line SGD. The conductive layer 24 contains, for example, tungsten.

The insulating layer 36 is provided on the conductive layer 24. The conductive layer 25 is provided on the insulating layer 36. The conductive layer 25 is formed in a line shape extending in the Y direction, for example, and is used as a bit line BL. Specifically, in a region not illustrated, a plurality of the conductive layers 25 are arranged along the X direction. The conductive layer 25 contains, for example, copper.

The insulating layer 37 is provided on the conductive layer 25. The insulating layer 37 includes a circuit and the like for connecting the memory cell array 10 to the row decoder module 15 and the sense amplifier module 16. For example, the insulating layer 37 can include conductive layers 44 and 45. The conductive layer 44 is provided in a layer of a higher level than the conductive layer 25, and is spaced apart from the conductive layer 25. The conductive layer 45 is provided in a layer of a higher level than the conductive layer 44, and is spaced apart from the conductive layer 44.

Each of the memory pillars MP is provided to extend in the Z direction, and penetrates the insulating layers 33 to 35 and the conductive layers 22 to 24. A bottom portion of the memory pillar MP reaches the conductive layer 21. A portion where the memory pillar MP and the conductive layer 22 intersect functions as the select transistor STS. A portion where the memory pillar MP and one conductive layer 23 intersect functions as one memory cell transistor MT. A portion where the memory pillar MP and the conductive layer 24 intersect functions as the select transistor STD.

In addition, each of the memory pillars MP includes, for example, a core member 50, a semiconductor layer 51, and a stacked film 52. The core member 50 is provided to extend in the Z direction. For example, the upper end of the core member 50 is included in a layer of a higher level than the conductive layer 24, and the lower end of the core member 50 is included in a wiring layer in which the conductive layer 21 is provided. The semiconductor layer 51 covers the periphery of the core member 50. A part of the semiconductor layer 51 is in contact with the conductive layer 21 via side surfaces of the memory pillar MP. The stacked film 52 covers the side surfaces and the bottom surface of the semiconductor layer 51 except for a portion where the semiconductor layer 51 and the conductive layer 21 are in contact with each other. The core member 50 contains an insulator such as silicon oxide. The semiconductor layer 51 contains, for example, silicon.

A columnar contact CV is provided on the semiconductor layer 51 in the memory pillar MP. In the illustrated region, two contacts CV corresponding to two memory pillars MP, among six memory pillars MP, are depicted. In the memory region MA, the memory pillar MP, which does not overlap the slit SHE and is not connected to the contact CV, is connected to a contact CV in a region not illustrated.

An upper part of the contact CV is in contact with one conductive layer 25, that is, one bit line BL. One contact CV is connected to one conductive layer 25 in each of spaces separated by the slits SLT and SHE. Specifically, the memory pillar MP provided between mutually neighboring slits SLT and SHE, and the memory pillar MP provided between two mutually neighboring slits SHE, are electrically connected to each of the conductive layers 25.

The slit SLT includes a portion provided along the XZ plane, for example, and divides the conductive layers 22 to 24 and the insulating layers 33 to 35. The contact LC in the slit SLT is provided along the slit SLT. A part of the upper end of the contact LC is in contact with the insulating layer 36. The lower end of the contact LC is in contact with the conductive layer 21. The contact LC is used, for example, as a part of the source line SL. The spacers SP are provided at least between the contact LC and the conductive layers 22 to 24. The contact LC is separated and insulated by the spacers SP from the conductive layers 22 to 24.

The slit SHE includes a portion provided along the XZ plane, for example, and divides at least the conductive layer 24. The upper end of the slit SHE is in contact with the insulating layer 36. The lower end of the slit SHE is in contact with the insulating layer 35. The slit SHE contains an insulator such as silicon oxide. The upper end of the slit SHE and the upper end of the slit SLT may or may not be aligned. Furthermore, the upper end of the slit SHE and the upper end of the memory pillar MP may or may not be aligned.

Hereinafter, wiring layers in which the conductive layers 41, 42 and 43 are provided are referred to as “D0”, “D1” and “D2”, respectively. The contact C0 connected to the semiconductor substrate 20, and the conductive layer 41 which are provided on the contact C0, contact

C1 . . . , and . . . , are referred to as “contact portion CP”. Wiring layers in which the conductive layers 25, 44 and 45 are provided are referred to as “M0”, “M1” and “M”, respectively.

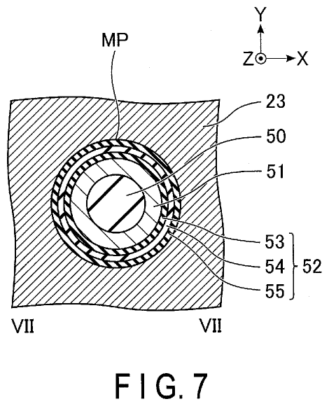

FIG. 7 is a cross-sectional view taken along a line VII-VII of FIG. 6, FIG. 7 illustrating an example of cross-sectional structure of the memory pillar MP in the semiconductor memory device 1 according to the first embodiment. FIG. 7 illustrates the cross-sectional structure of the memory pillar MP in a layer parallel to the surface of the semiconductor substrate 20 and including the conductive layer 23. As illustrated in FIG. 7, the stacked film 52 includes, for example, a tunnel insulating film 53, an insulating film 54, and a block insulating film 55.

In a cross section including the conductive layer 23, the core member 50 is provided in a central portion of the memory pillar MP. The semiconductor layer 51 surrounds the side surface of the core member 50. The tunnel insulating film 53 surrounds the side surface of the semiconductor layer 51. The insulating film 54 surrounds the side surface of the tunnel insulating film 53. The block insulating film 55 surrounds the side surface of the insulating film 54. The conductive layer 23 surrounds the side surface of the block insulating film 55. Each of the tunnel insulating film 53 and the block insulating film 55 contains, for example, silicon oxide. The insulating film 54 contains, for example, silicon nitride.

In each of the memory pillars MP described above, the semiconductor layer 51 is used as a channel (current path) of the memory cell transistors MT0 to MT7 and the select transistors STD and STS. The insulating film 54 is used as a charge storage layer of the memory cell transistor MT. The semiconductor memory device 1 can cause a current to flow via the memory pillar MP between the bit line BL and the contact LC by turning on the memory cell transistors MT0 to MT7 and the select transistors STD and STS.

(Structure of Semiconductor Memory Device 1 in Hookup RegionHA1 and Contact Region C3T)

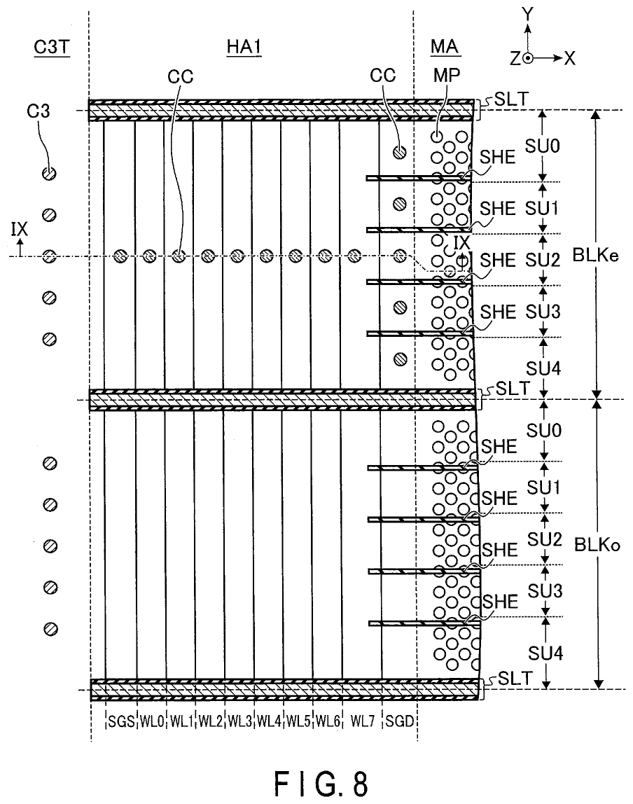

FIG. 8 is a plan view illustrating an example of a plan layout in the hookup region HA1 and the contact region C3T of the semiconductor memory device 1 according to the first embodiment. FIG. 8 illustrates a region corresponding to mutually neighboring blocks BLKe and BLKo in the hookup region HA1, and a part of the memory region MA and contact region C3T. “BLKe” corresponds to an even-numbered block BLK. “BLKo” corresponds to an odd-numbered block ELK.

As illustrated in FIG. 8, the semiconductor memory device 1 includes a plurality of contacts CC in the hookup regionHA1, and a plurality of contacts C3 in the contact region C3T. The contact CC is connected to any one of the conductive layers 22 to 24 provided in the memory cell array 10. The contact C3 is used, for example, for connection between the contact CC and the row decoder module 15.

In addition, in the hookup regionHA1, each of the select gate line SGS, the word lines WL0 to WL7, and the select gate line SGD includes a portion (terrace portion) that does not overlap an upper wiring layer (conductive layer). In this example, a plurality of the terrace portions of the select gate line SGD are provided.

In the hookup regionHA1, the shape of the portion that does not overlap the upper wiring layer is similar to that of a step, a terrace, a rimstone, or the like. Specifically, level differences are respectively provided between the select gate line SGS and the word line WL0, between the word line WL0 and the word line WL1, . . . , between the word line WL6 and the word line WL7, and between the word line WL7 and the select gate line SGD. In this example, a staircase structure having a level difference in the X direction is formed by an end portion of the select gate line SGS, end portions of the word lines WL0 to WL7, and an end portion of the select gate line SGD.

In a region where the hookup regionHA1 and the block BLKe overlap, the plurality of contacts CC are provided on the terrace portions of the select gate line SGS, the word lines WL0 to WL7, and the select gate lines SGD0 to SGD4, respectively. Besides, in a region where the hookup region HAl and the block BLKo overlap, the contacts CC for the stacked wiring lines are omitted.

Although illustration is omitted, in a region where the hookup region HA2 and the block BLKo overlap, a plurality of contacts CC are provided on terrace portions of the select gate line SGS, the word lines WL0 to WL7, and the select gate lines SGD0 to SGD4, respectively. Besides, in a region where the hookup region HA2 and the block BLKe overlap, the contacts CC for the stacked wiring lines are omitted.

Specifically, in the semiconductor memory device 1 according to the first embodiment, a plan layout of the block BLKo in the hookup region HA2 is similar to a layout in which the structure of the block BLKe in the hookup regionHA1 is inverted in each of the X direction and the Y direction. A plan layout of the block BLKe in the hookup region HA2 is similar to a layout in which the structure of the block BLKo in the hookup regionHA1 is inverted in each of the X direction and the Y direction.

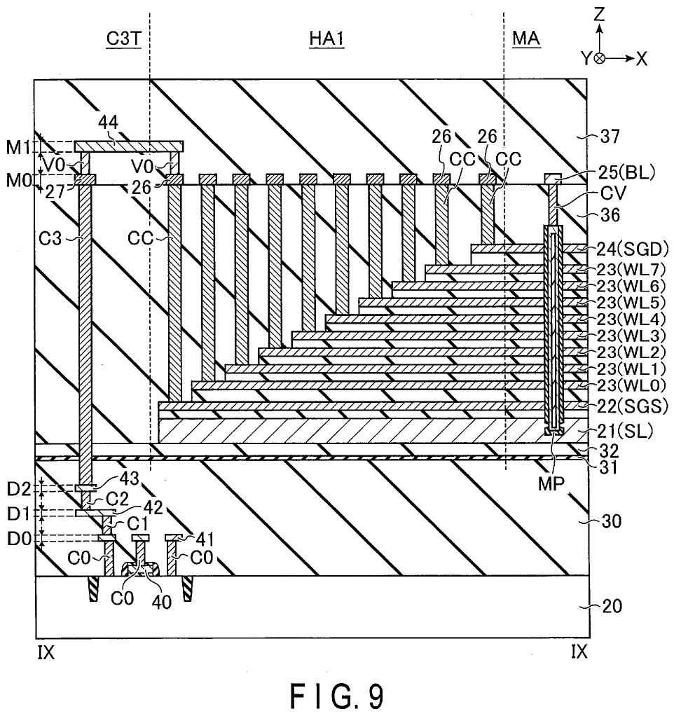

FIG. 9 is a cross-sectional view taken along a line IX-IX of FIG. 8, FIG. 9 illustrating an example of cross-sectional structure in the hookup regionHA1 and the contact region C3T of the semiconductor memory device 1 according to the first embodiment. As illustrated in FIG. 9, the semiconductor memory device 1 further includes a conductive layer 27 in the contact region C3T. An end portion of a stacked wiring structure corresponding to the memory cell array 10 is provided in a staircase pattern by the end portion of each of the select gate line SGS, the word lines WL0 to WL7, and the select gate line SGD.

The contacts CC are provided on the terrace portions of the select gate line SGS, the word lines WL0 to WL7, and the select gate line SGD, respectively. One conductive layer 26 is provided on each contact CC. The conductive layer 26 is included in the same wiring layer as the conductive layer 25, for example. A contact V0 is provided on the conductive layer 26. FIG. 9 illustrates the contact V0 which corresponds to the select gate line SGS among the contacts V0. The conductive layer 44 is provided on the contact V0.

The contact C3 is provided on the conductive layer 43, and penetrates the insulating layers 31, 32, and 36. The conductive layer 27 is provided on the contact C3. FIG. 9 illustrates one set of the conductive layer 27 and the contact C3, which is associated with the select gate line SGS, among the sets of the conductive layer 27 and the contact C3. The conductive layer 27 is included in the same wiring layer as the conductive layer 26. The contact V0 is provided on the conductive layer 27 associated with the select gate line SGS. The conductive layer 44 is provided on the contact V0.

Thereby, the conductive layer 22 corresponding to the select gate line SGS is electrically connected to a transistor provided in a lower layer than the insulating layer 31 via one set of the contacts CC and C3. Each of the conductive layers 23 and 24 included in the stacked wiring structure corresponding to the memory cell array 10 is also electrically connected to a transistor provided in a lower layer than the insulating layer 31 via one set of the contacts CC and C3, similarly to the conductive layer 22. Specifically, each of the select gate line SGS, the word lines WL0 to WL7, and the select gate lines SGD0 to SGD4 is electrically connected to the row decoder module 15 via a corresponding set of the contacts CC and C3.

Note that it suffices that the semiconductor memory device 1 has a configuration in which a voltage can be applied to each of the select gate line SGS, the word lines WL0 to WL7, and the select gate lines SGD0 to SGD4 from the contact CC disposed in at least one of the hookup regions HA1 or HA2. The contact CC may be connected to each wiring layer in each of the hookup regionHA1 and the hookup region HA2. In this case, for example, a voltage is applied to the word line WL from each of the contact CC in the hookup regionHA1 and the contact CC in the hookup region HA2. Furthermore, the hookup region HA may be inserted in an intermediate portion of the memory region MA. In this case, for example, the word line WL is electrically connected to a transistor provided in a lower layer than the insulating layer 31 via a contact penetrating the stacked wiring structure of the memory cell array 10.

(Configuration of Semiconductor Memory Device 1 Including Source Line SL)

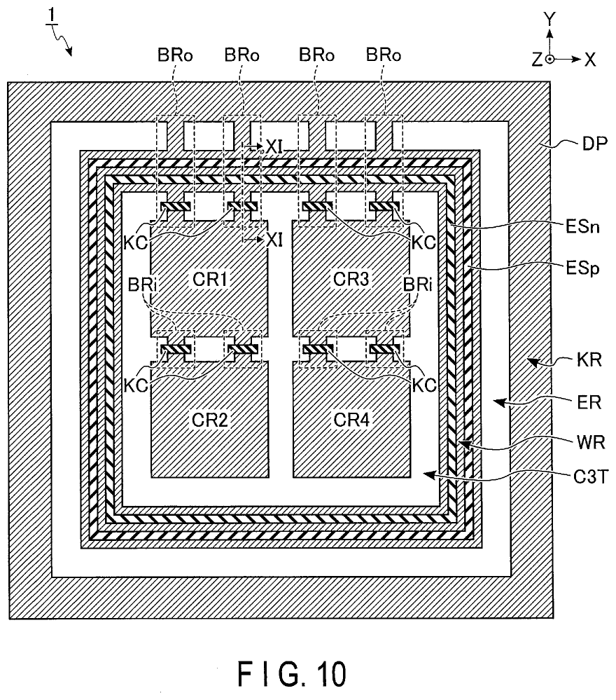

FIG. 10 is a plan view illustrating an example of a configuration in a wiring layer including the source line SL of the semiconductor memory device 1 according to the first embodiment. FIG. 10 illustrates the same region as the plan layout of the semiconductor memory device 1 according to the first embodiment illustrated in FIG. 3. As illustrated in FIG. 10, the semiconductor memory device 1 includes a conductive portion DP, a plurality of dividing portions KC, and sealing members ESn and ESp in the wiring layer including the source line SL.

The conductive portion DP is provided on entire surfaces of, for example, the core region CR, the wall region WR, and the kerf region KR. The conductive portion DP is used as a current path which suppresses the influence of arcing that occurs during manufacturing of the semiconductor memory device 1. The conductive portion DP in the core region CR is used also a part of the source line SL. The conductive portion DP includes, for example, a plurality of bridge portions BRo and a plurality of bridge portions BRi.

The bridge portion BRo is provided to extend in the Y direction, for example. In the bridge portion BRo, the conductive portion DP in the core region CR1 and the conductive portion DP in the wall region WR are connected together, and the conductive portion DP in the wall region WR and the conductive portion DP in the kerf region KR are connected together. In the present example, two bridge portions BRo are provided in association with each of the core regions CR1 and CR3. In the bridge portion BRo, the arrangement between a portion where the conductive portion DP in the core region CR and the conductive portion DP in the wall region WR are connected together, and a portion where the conductive portion DP in the wall region WR and the conductive portion DP in the kerf region KR are connected together, can freely be designed.

The bridge portion BRi is provided to extend in the Y direction, for example. In the bridge portion BRi, the conductive portions DP in the core regions CR, which neighbor each other in the Y direction, are connected. In the present example, two bridge portions BRi are provided between the core regions CR1 and CR2. Similarly, two bridge portions BRi are provided between the core regions CR3 and CR4. It is preferable that at least one of the two core regions CR, which are connected to the bridge portions BRi, is directly or indirectly connected to the bridge portions BRo.

Note that at least one bridge portion BRo or BRi is preferably connected to each core region CR. The number of bridge portions BR connected to each core region CR can freely be designed. It suffices that, in the entirety of the semiconductor memory device 1, at least one portion, which connects the conductive portion DP in the wall region WR and the conductive portion DP in the kerf region KR, is provided.

The dividing portions KC are provided to overlap the bridge portions BR, respectively, and divide the conductive portions DP of the bridge portions BR. Conductive portions DP adjacent to each other via the dividing portion KC are insulated from each other by the dividing portion KC. In this example, the dividing portion KC is provided at each of a portion where the bridge portion BRo and the contact region C3T overlap and a portion where the bridge portion BRi and the contact region C3T overlap. Specifically, the dividing portions KC insulate the conductive portion DP connected to the sealing members ESn and ESp from the conductive portion DP disposed in the core region CR, and insulate the conductive portions DP of two core regions CR, which are connected by the bridge portion BRi, from each other. The number of dividing portions KC provided in one bridge portion BR may be one or more. The dividing portion KC may be referred to as a “kerf cut”.

The sealing member ESn is a structure capable of releasing positive charge generated inside and outside the wall region WR to the semiconductor substrate 20. The sealing member ESp is a structure capable of releasing negative charge generated inside and outside the wall region WR to the semiconductor substrate 20. Each of the sealing members ESn and ESp is provided in a square ring shape in a manner to surround the outer periphery of the core regions CR1 to CR4 in the wall region WR. The sealing member ESp surrounds the outer periphery of the sealing member ESn and is spaced apart from the sealing member ESn. Each of the sealing members ESn and ESp divides the conductive portion DP provided in the wall region WR, and is electrically insulated from the conductive portion DP, for example.

In addition, each of the sealing members ESn and ESp can suppress permeation of moisture or the like from the outside of the wall region WR into the core region CR. Each of the sealing members ESn and ESp can suppress stress generated in an interlayer insulating film (for example, tetraethoxysilane (TEOS)) of the semiconductor memory device 1. Furthermore, each of the sealing members ESn and ESp can also be used as a crack stopper. Specifically, each of the sealing members ESn and ESp can suppress a crack from reaching the inside of the semiconductor memory device 1 when the crack occurs in the peripheral portion of a chip on which the semiconductor memory device 1 is formed in the dicing process. Each of the sealing members ESn and ESp may be referred to as an “edge seal” or a “crack stopper”.

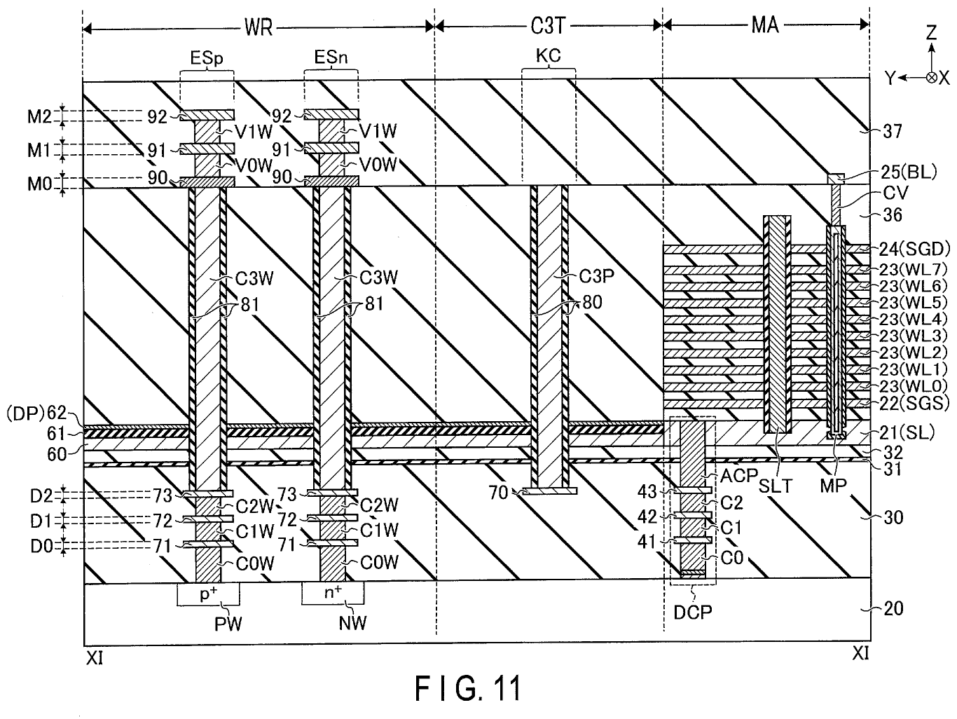

FIG. 11 is a cross-sectional view taken along a line XI-XI of FIG. 10, FIG. 11 illustrating an example of cross-sectional structure in the memory region MA, the contact region C3T and the wall region WR of the semiconductor memory device 1 according to the first embodiment. FIG. 11 includes a cross section along the bridge portion BR. As illustrated in FIG. 11, the semiconductor memory device 1 further includes a conductive layer 60, an insulating layer 61, and a conductive layer 62. The semiconductor memory device 1 includes a conductive layer 70, spacers 80, and a contact C3P in the contact region C3T. The semiconductor memory device 1 includes two sets of conductive layers 71, 72, 73, 90, 91, and 92, and contacts C0W, C1W, C2W, C3W, V0W, and V1W in the wall region WR. The semiconductor substrate 20 includes an N-type impurity diffusion region NW and a P-type impurity diffusion region PW.

The conductive layer 60 is provided on the insulating layer 32. The insulating layer 61 is provided on the conductive layer 60. The conductive layer 62 is provided on the insulating layer 61. The upper surface of the conductive layer 62 and the upper surface of the conductive layer 21 are aligned. A set of the conductive layer 60, insulating layer 61 and conductive layer 62 is provided at the same height as the source line SL. A planar shape of the set of the conductive layer 60, insulating layer 61 and conductive layer 62 corresponds to a planar shape of the conductive portion DP. In the vicinity of the boundary between the memory region MA and the contact region C3T, the conductive layer 60 and the conductive layer 21 are electrically connected together and contiguously provided. In the vicinity of the boundary between the memory region MA and the contact region C3T, the conductive layer 62 and the conductive layer 21 are electrically connected together and contiguously provided. The conductive layer 62 is used as the conductive portion DP. The conductive layer 62 is, for example, silicon. The conductive layer 70 is included in the wiring layer D2. The contact C3P is provided on the conductive layer 70. The contact C3P divides the insulating layers 31 and 32, conductive layer 60, insulating layer 61, conductive layer 62 and insulating layer 36. The contact C3P is a plate-shaped conductor extending along the XZ plane. The spacers 80 are insulators provided on the side surfaces of the contact C3P. The contact C3P is sandwiched by the spacers 80. The contact C3P is separated and insulated by the spacers 80 from conductors (for example, the conductive layer 60 and conductive layer 62) adjacent to the contact C3P in the Y direction. The spacer 80 is, for example, a silicon oxide film. A set of the contact C3P and the spacers 80 corresponds to the dividing portion KC. It suffices that the dividing portion KC insulates at least mutually neighboring conductors, and the dividing portion KC may not include the contact C3P.

The conductive layers 71, 72, 73, 90, 91, and 92 are included in the wiring layers D0, D1, D2, M0, M1, and M2, respectively. The contact C0W is provided on the semiconductor substrate 20. The conductive layer 71 is provided on the contact C0W. The contact C1W is provided on the conductive layer 71. The conductive layer 72 is provided on the contact C1W. The contact C2W is provided on the conductive layer 72. The conductive layer 73 is provided on the contact C2W. The contact C3W is provided on the conductive layer 73. A set of the contacts C0W, C1W, C2W, and C3W and the conductive layers 71, 72, and 73 divides the insulating layer 30. Furthermore, the contact C3W divides the insulating layers 31 and 32, conductive layer 60, insulating layer 61, conductive layer 62 and insulating layer 36. The upper surface of the contact C3W and the upper surface of the contact C3P are aligned. The height of the upper surfaces of the contacts C3W and C3P is greater than the height of the upper surface of the memory pillar MP. Spacers 81 are insulators provided on side surfaces of the contact C3W. The contact C3W is sandwiched by, for example, the spacers 81. The contact C3W is separated by, for example, the spacers 81 from the insulating layer 36 adjacent to the contact C3W. The spacer 81 is, for example, a silicon oxide film.

The conductive layers 90, 91, and 92 are included in the wiring layers M0, Ml, and M2, respectively. The conductive layer 90 is provided on the contact C3W. The contact V0W is provided on the conductive layer 90. The conductive layer 91 is provided on the contact V0W. The contact V1W is provided on the conductive layer 91. The conductive layer 92 is provided on the contact V1W. A set of the contacts V0W and V1W and the conductive layers 90, 91, and 92 divides the insulating layer 37.

In a region not illustrated, a set of the contacts C0W, C1W, C2W, C3W, V0W and V1W and the conductive layers 71, 72, 73, 90, 91 and 92 includes a portion extending in the Y direction. In addition, the set of the contacts C0W, C1W, C2W, C3W, V0W and V1W and the conductive layers 71, 72, 73, 90, 91 and 92 includes a portion extending in the X direction. Thereby, the set of the contacts C0W, C1W, C2W, C3W, V0W and V1W and the conductive layers 71, 72, 73, 90, 91 and 92 is provided, for example, in a square ring shape, and surrounds the core regions CR.

Each of the contacts C0W, C1W, C2W, C3W, V0W and V1W is, for example, a metal. A set of the conductive layers 71, 72, 73, 90, 91, and 92 and the contacts C0W, C1W, C2W, C3W, V0W and V1W corresponds to either the sealing member ESn or ESp. The set of the conductive layers 71, 72, 73, 90, 91, and 92 and the contacts C0W, C1W, C2W, C3W, V0W and V1W corresponding to the sealing member ESn is connected to the N-type impurity diffusion region NW of the semiconductor substrate 20. The set of the conductive layers 71, 72, 73, 90, 91, and 92 and the contacts C0W, C1W, C2W, C3W, V0W and V1W corresponding to the sealing member ESp is connected to the P-type impurity diffusion region PW of the semiconductor substrate 20. Each of the sealing members ESn and ESp can be regarded as a wall between the core region CR and the kerf region KR.

Note that it suffices that the sealing member ESn is connected to at least the N-type impurity diffusion region NW. If the N-type impurity diffusion region NW has a sufficient area as a discharge path, the N-type impurity diffusion region NW may not necessarily be provided in a square ring shape. The N-type impurity diffusion region NW is formed, for example, in a P-type well region of the semiconductor substrate 20. Similarly, it suffices that the sealing member ESp is connected to at least the P-type impurity diffusion region PW. If the P-type impurity diffusion region PW has a sufficient area as a discharge path, the P-type impurity diffusion region PW may not necessarily be provided in a square ring shape. The P-type impurity diffusion region PW is formed, for example, in a P-type well region of the semiconductor substrate 20.

Furthermore, the semiconductor memory device 1 according to the first embodiment includes at least one discharge-path contact portion DCP in the core region CR, for example, in the memory region MA. The discharge-path contact portion DCP includes a contact ACP. The contact ACP is provided on a path which electrically connects the source line SL and the semiconductor substrate 20. The contact ACP is in contact with the conductive layer 21. The contact ACP may be electrically connected to the conductive layers 60 and 62, and it suffices that the contact ACP is electrically connected to at least the source line SL in the memory region MA.

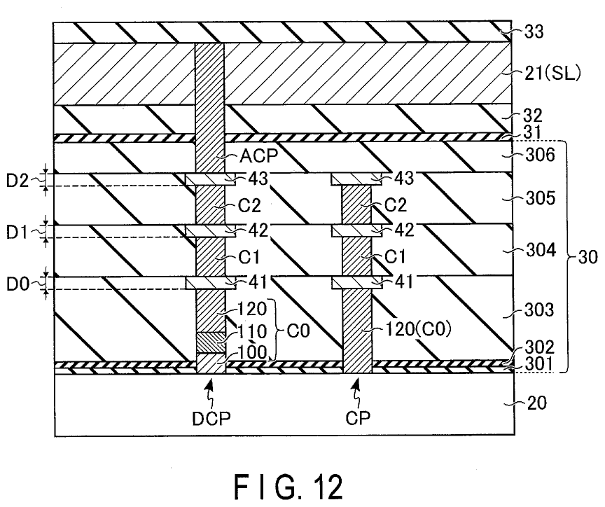

FIG. 12 is a cross-sectional view illustrating an example of cross-sectional structure including the discharge-path contact portion DCP and the contact portion CP of the semiconductor memory device according to the first embodiment. As illustrated in FIG. 12, the insulating layer 30 includes an oxide film 301, a nitride film 302, and insulating layers 303, 304, 305 and 306. The discharge-path contact portion DCP includes, for example, contacts C0, C1, C2 and ACP and conductive layers 41, 42 and 43. The contact portion CP includes, for example, contacts C0, C1 and C2 and conductive layers 41, 42 and 43.

The oxide film 301, nitride film 302 and insulating layers 303, 304, 305 and 306 are provided in the named order on the semiconductor substrate 20. The insulating layer 31 is provided on the insulating layer 306. The oxide film 301, nitride film 302 and insulating layer 303 are included in a layer between the surface of the semiconductor substrate 20 and an upper end of the wiring layer D0. The oxide film 301 and nitride film 302 protect transistors which constitute peripheral circuits. The insulating layer 304 is included in a layer between a lower end of the contact C1 and an upper end of the wiring layer D1. The insulating layer 305 is included in a layer between a lower end of the contact C2 and an upper end of the wiring layer D2. The insulating layer 306 is included in a layer between an upper end of the wiring layer D2 and a lower end of the insulating layer 31.

The contact C0 of the discharge-path contact portion DCP includes semiconductor layers 100 and 110 and a conductive layer 120. In the discharge-path contact portion DCP, the semiconductor layer 100 is provided on the semiconductor substrate 20. The semiconductor layer 110 is provided on the semiconductor layer 100. The conductive layer 120 is provided on the semiconductor layer 110. For example, the height of the upper end of the semiconductor layer 100 is greater than the height of that part of the nitride film 302, which is penetrated by the contact C0.

The semiconductor layer 100 is an epitaxial layer or a polysilicon layer. The semiconductor layer 110 is doped with P-type impurities (e.g. boron) at a low concentration. The semiconductor layer 110 has the same crystal structure as the semiconductor layer 100, and contains P-type impurities (e.g. boron) at a low concentration, like the semiconductor layer 100. Furthermore, the semiconductor layer 110 contains N-type impurities (e.g. arsenic or phosphorus) at a high concentration. Thereby, a PN-junction diode is formed between the semiconductor layer 100 and the semiconductor layer 110. In addition, a direction from the semiconductor layer 100 toward the semiconductor layer 110 corresponds to a forward direction of the PN-junction diode, and a direction from the semiconductor layer 110 toward the semiconductor layer 100 corresponds to a reverse direction of the PN-junction diode.

Note that the concentration of P-type impurities doped in the semiconductor layer 100 is preferably in a range of 10¹⁴ to 10¹⁶ (atoms/cm³). The concentration of N-type impurities doped in the semiconductor layer 110 is preferably 10²⁰ (atoms/cm³) or more. The PN-junction diode formed with this structure can increase a depletion layer width, and can increase a breakdown voltage. Note that if the depletion layer width of the PN-junction diode can appropriately be designed by an impurity concentration gradient formed by the semiconductor layers 100 and 110, the semiconductor layer 100 may contain P-type impurities at a high concentration, and the semiconductor layer 110 may contain N-type impurities at a high concentration.

The conductive layer 41 is provided on the conductive layer 120. The contact C1 is provided on the conductive layer 41. The conductive layer 42 is provided on the contact C1. The contact C2 is provided on the conductive layer 42. The conductive layer 43 is provided on the contact C2. The contact ACP is provided on the conductive layer 43. The contact ACP penetrates the conductive layer 21 and the insulating layers 31, 32 and 306. The side surface of the contact ACP is in contact with the conductive layer 21 at the height of the layer including the conductive layer 21. Note that when the contact ACP penetrates the conductive layers 60 and 62, the side surface of the contact ACP is in contact with the conductive layers 60 and 62 at the height of the layer including the conductive layer 21. The contact ACP functions as a part of the current path between the source line SL and the PN-junction diode in the contact C0.

The contact C0 in the contact portion CP includes, for example, a conductive layer 120. The conductive layer 120 in the contact portion CP is provided on the semiconductor substrate 20 and is in contact with the conductive layer 41. The conductive layer 120 in the discharge-path contact portion DCP and the conductive layer 120 in the contact portion CP contain, for example, tungsten. Depending on manufacturing methods, the conductive layer 120 and conductive layer 41 may be integrally provided in the discharge-path contact portion DCP, and the conductive layer 120 and conductive layer 41 may be integrally provided in the contact portion CP. The other structure of the contact portion CP is the same as the structure of the discharge-path contact portion DCP, except that the contact portion CP does not include the contact ACP.

### [1-2] Manufacturing Method of Semiconductor Memory Device 1

[1-2-1] Method of Forming Contact C0 and Conductive Layer 41

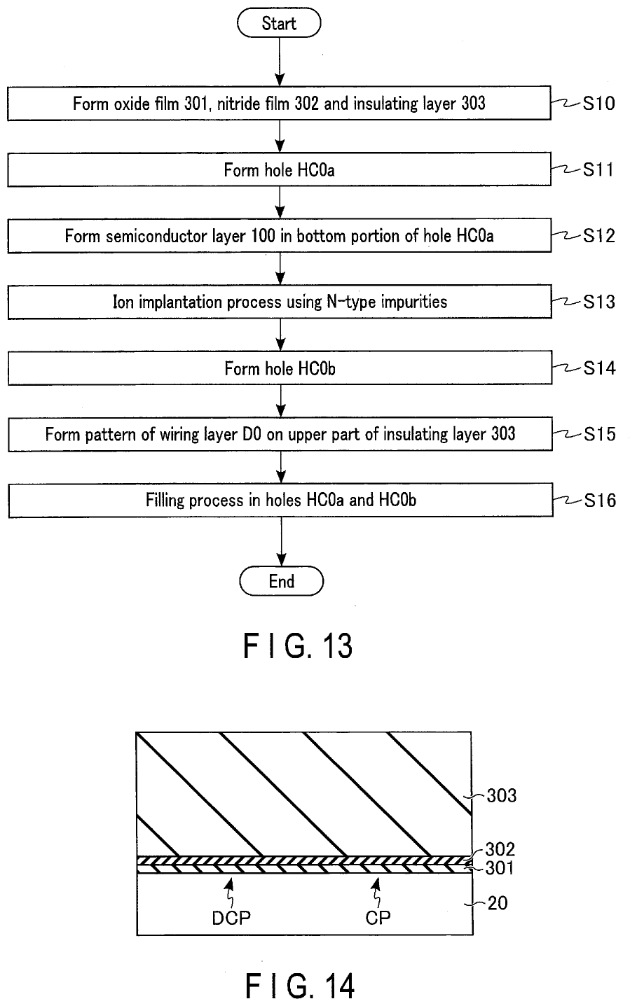

FIG. 13 is a flowchart illustrating an example of a method for manufacturing the semiconductor memory device 1 according to the first embodiment, and FIG. 13 illustrates an example of manufacturing steps relating to the formation of the contact C0 and conductive layer 41. FIGS. 14 to 20 are cross-sectional views illustrating an example of cross-sectional structure during manufacturing of the semiconductor memory device 1 according to the first embodiment. Each of FIG. 14 to FIG. 20 illustrates a region where one discharge-path contact portion DCP and one contact portion CP are formed. As illustrated in FIG. 13, the forming steps of the contact C0 and conductive layer 41 include steps S10 to S16.

To start with, by a process of step S10, as illustrated in FIG. 14, an oxide film 301, a nitride film 302 and an insulating layer 303 are formed. Specifically, a transistor or the like used in the peripheral circuit is formed on the semiconductor substrate 20. Then, the formed transistor is covered and protected by the oxide film 301 and nitride film 302. Further, the insulating layer 303 is buried in a stepped portion formed by the transistor or the like, and the upper surface of the insulating layer 303 is planarized.

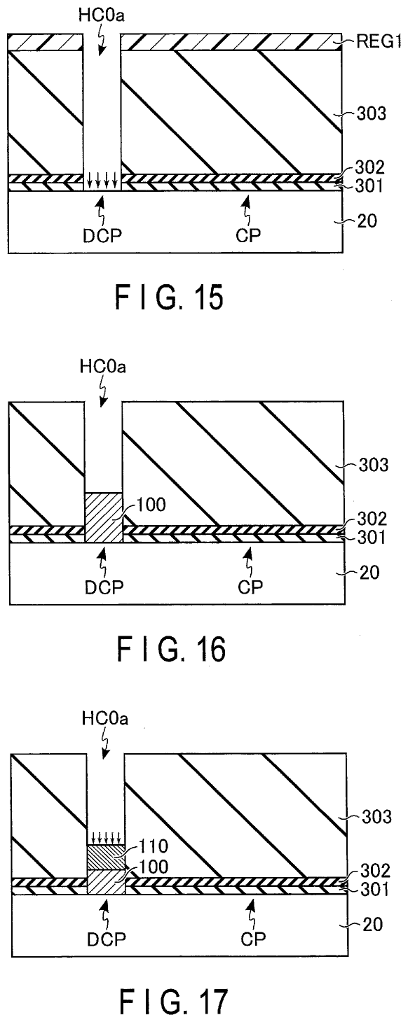

Next, by a process of step S11, as illustrated in FIG. 15, a hole HC0a is formed. In the formation of the hole HC0a, at first, by photolithography, for example, a mask REG1 with an opening in a part of the hole HC0a is formed. Then, an anisotropic etching process using the mask REG1 is executed. As the anisotropic etching process, for example, RIE (Reactive Ion Etching) is used. The hole HC0a penetrates the insulating layer 303, nitride film 302 and oxide film 301, and a surface of the semiconductor substrate 20 is exposed at a bottom portion of the hole HCoa. The shape of the hole HC0a corresponds to the shape of the contact C0 of the discharge-path contact portion DCP. After the hole HC0a is formed, the mask REG1 is removed.

Subsequently, by a process of step S12, as illustrated in FIG. 16, a semiconductor layer 100 is formed at the bottom portion of the hole HC0a. When the semiconductor layer 100 is a polysilicon layer, a semiconductor film is first formed in a manner to fill the hole HC0a. Thereafter, by executing an etch-back process, the semiconductor layer 100 in the hole HC0a is processed to have a desired height. When the semiconductor layer 100 is an epitaxial layer, the semiconductor layer 100 is formed by epitaxial growth based on that part of the semiconductor substrate 20, which is exposed at the bottom portion of the hole HC0a. In addition, in the process of step S12, P-type impurities (e.g. boron) are doped in the semiconductor layer 100 at a low concentration. The height of the semiconductor layer 100 formed by the process of step S12 corresponds to the total height of the semiconductor layers 100 and 110 described with reference to FIG. 12.

Next, by a process of step S13, as illustrated in FIG. 17, an ion implantation process using N-type impurities is executed. In the ion implantation process, N-type impurities (e.g. arsenic, phosphorus) are implanted in that part of the semiconductor layer 100, which is exposed in the hole HC0a. The portion in which the N-type impurities are implanted by the process of step S13 functions as an N-type semiconductor layer 110.

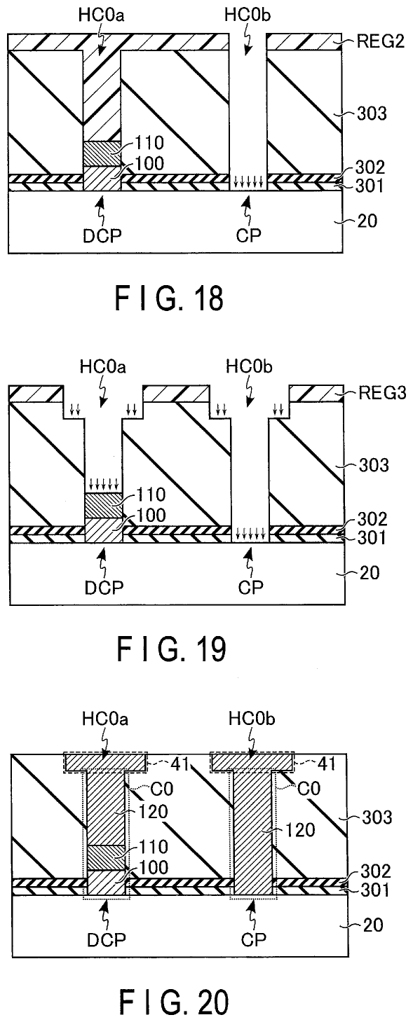

Following the above, by a process of step S14, as illustrated in FIG. 18, a hole HC0b is formed. In the formation of the hole HC0b, at first, by photolithography, for example, a mask REG2 with an opening in a part of the hole HC0b is formed. Then, an anisotropic etching process using the mask REG2 is executed. As the anisotropic etching process, for example, RIE is used. The hole HC0b penetrates the insulating layer 303, nitride film 302 and oxide film 301, and a surface of the semiconductor substrate 20 is exposed at a bottom portion of the hole HC0b. The shape of the hole HC0b corresponds to the shape of the contact C0 of the contact portion CP. After the hole HC0b is formed, the mask REG2 is removed.

Next, by a process of step S15, as illustrated in FIG. 19, a pattern of a wiring layer D0 is formed on an upper part of the insulating layer 303. In the formation of the pattern of the wiring layer D0, at first, for example, by photolithography, a mask REG3 with an opening in a portion of the pattern of the wiring layer D0 is formed. The opening of the mask REG3 includes a portion where the pattern of the wiring layer D0 and the hole HC0a overlap, and a portion where the pattern of the wiring layer D0 and the hole HC0b overlap. Then, an anisotropic etching process using the mask REG3 is executed. As the anisotropic etching process, for example, RIE is used. In this etching process, the pattern of the wiring layer D0 is transferred onto the upper part of the insulating layer 303, and a part of each of the upper portion of the hole HC0a and the upper portion of the hole HC0b is etched. After the pattern of the wiring layer D0 is formed, the mask REG3 is removed. Note that, by the process of step S15, each of the surface of the semiconductor layer 110 exposed in the hole HC0a and the surface of the semiconductor substrate 20 exposed in the hole HC0b may be etched within such a range as not to affect the operation of the semiconductor memory device 1.

Subsequently, by a process of step S16, as illustrated in FIG. 20, a filling process of the hole HC0a and hole HC0b is executed. Specifically, at first, a conductor is formed in a manner to fill the hole HC0a and hole HC0b. This conductor is formed by, for example, CVD (Chemical Vapor Deposition). In addition, a conductor formed outside the hole HC0a and hole HC0b is removed by CMP (Chemical Mechanical Polishing). Thereby, in the discharge-path contact portion DCP, a portion corresponding to the conductive layer 120 and a portion corresponding to the conductive layer 41 are continuously formed in the hole HC0a. In the contact portion CP, a portion corresponding to the conductive layer 120 and a portion corresponding to the conductive layer 41 are continuously formed in the hole HC0b. A method in which the conductor of the contact C0 and the conductor in the wiring layer D0 are formed batchwise in this manner is also called “dual damascene method”.

By the above-described manufacturing steps, the structure corresponding to the contact C0 and the conductive layer 41 is formed in the discharge-path contact portion DCP, and the structure corresponding to the contact C0 and the conductive layer 41 is formed in the contact portion CP. Note that the above-described manufacturing steps are merely examples, and another process may be inserted between the manufacturing steps, and the order of manufacturing steps may be changed as far as no problem will occur. In the present example, the case was illustrated in which the dual damascene method is used for forming the contact C0 and the conductive layer 41, but the conductive layer 120 and the conductive layer 41 may be formed in different steps.

### [1-2-2] Method for Forming Contact ACP and Memory Cell Array 10

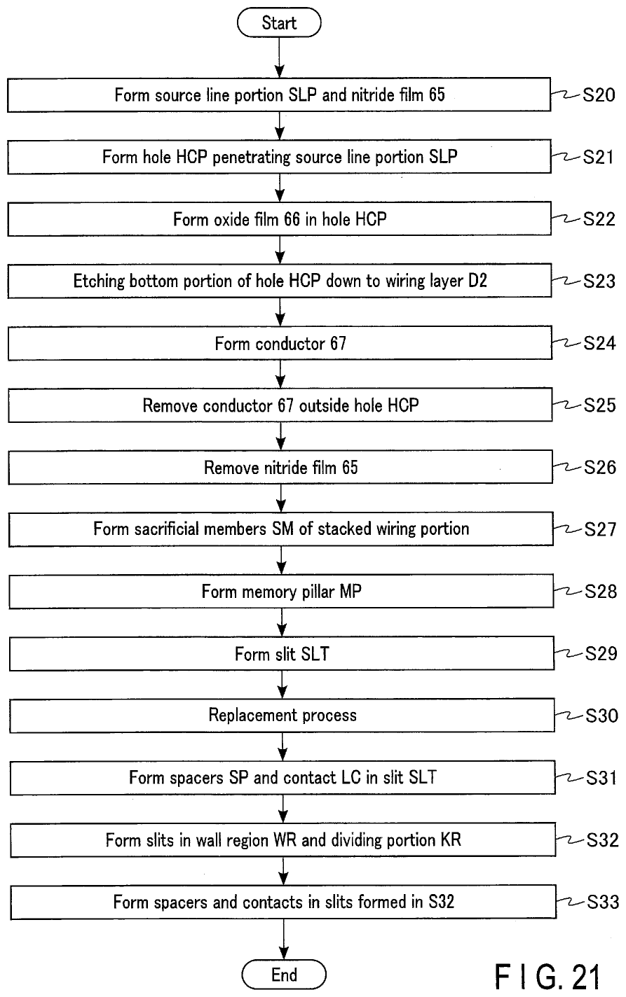

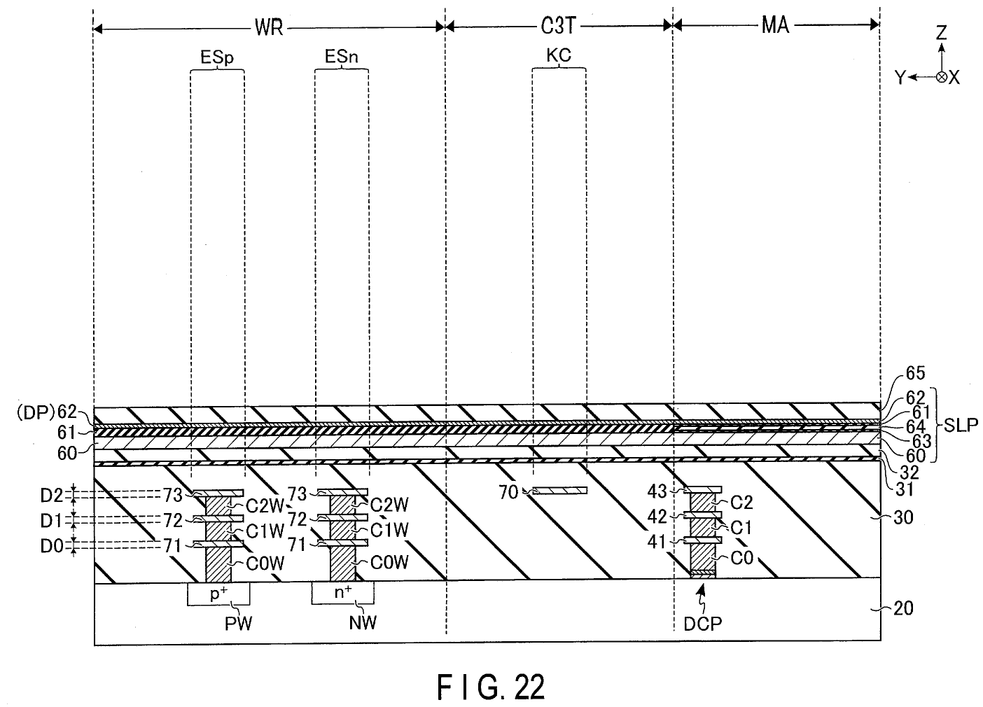

FIG. 21 is a flowchart illustrating an example of a method for manufacturing the semiconductor memory device 1 according to the first embodiment, and FIG. 21 illustrates an example of manufacturing steps relating to the formation of the contact ACP and memory cell array 10. FIGS. 22 to 32 are cross-sectional views illustrating an example of cross-sectional structure during manufacturing of the semiconductor memory device 1 according to the first embodiment. Each of FIG. 22 to FIG. 32 illustrates the same region as the cross-sectional structure of the semiconductor memory device 1 illustrated in FIG. 11, and includes a region in which the sealing members ESn and ESp and the dividing portion KC are formed. As illustrated in FIG. 21, the steps of forming the contact ACP and the memory cell array 10 include steps S20 to S33.

To start with, by a process of step S20, as illustrated in FIG. 22, a source line portion SLP and a nitride film 65 are formed. The source line portion SLP is a stacked structure used for the formation of the source line SL. In brief, a structure of wiring layers D0 to D2 is formed, and an insulating layer 30 is formed, and thereafter insulating layers 31 and 32, a conductive layer 60, an insulating layer 63 and a sacrificial member 64 are formed in the named order on the insulating layer 30. Then, the insulating layer 63 and sacrificial member 64 provided outside the memory region MA are removed, and an insulating layer 61 and a conductive layer 62 are formed in the named order. At this time, it suffices that the sacrificial member 64 is removed at a portion corresponding to the dividing portion KC and at a portion corresponding to the sealing members ESn and ESp. The insulating layer 63 may remain in the contact region C3T and the wall region WR. The height of the insulating layer 61 may or may not be uniform between the memory region MA, and the contact region C3T and wall region WR. A set of the conductive layer 60, insulating layer 63, sacrificial member 64, insulating layer 61 and conductive layer 62 corresponds to the source line portion SLP. Then, the nitride film 65 is formed on the conductive layer 62.

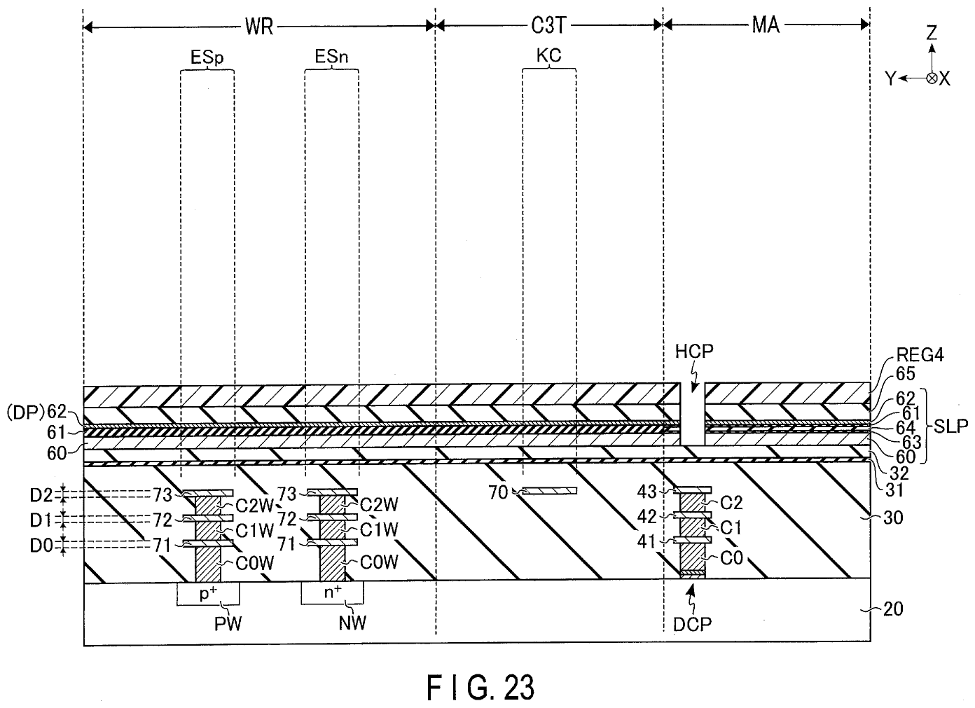

Next, by a process of step S21, as illustrated in FIG. 23, a hole HCP penetrating the source line portion SLP is formed. In the formation of the hole HCP, at first, by photolithography, for example, a mask REG4 with an opening in a part overlapping the discharge-path contact portion DCP is formed. Then, an anisotropic etching process using the mask REG4 is executed, and the hole HCP is formed. As the anisotropic etching process, for example, RIE is used. The hole HCP penetrates the nitride film 65, conductive layer 62, insulating layer 61, sacrificial member 64, insulating layer 63 and conductive layer 60, and a surface of the insulating layer 32 is exposed at a bottom portion of the hole HCP. After the hole HCP is formed, the mask REG4 is removed. Note that in the process of step S21, in a region not illustrated, layers (the conductive layer 62, insulating layer 61, conductive layer 60), which are provided at the same height as the source line portion SLP at the periphery of the core region CR, are removed except for the bridge portion BR.

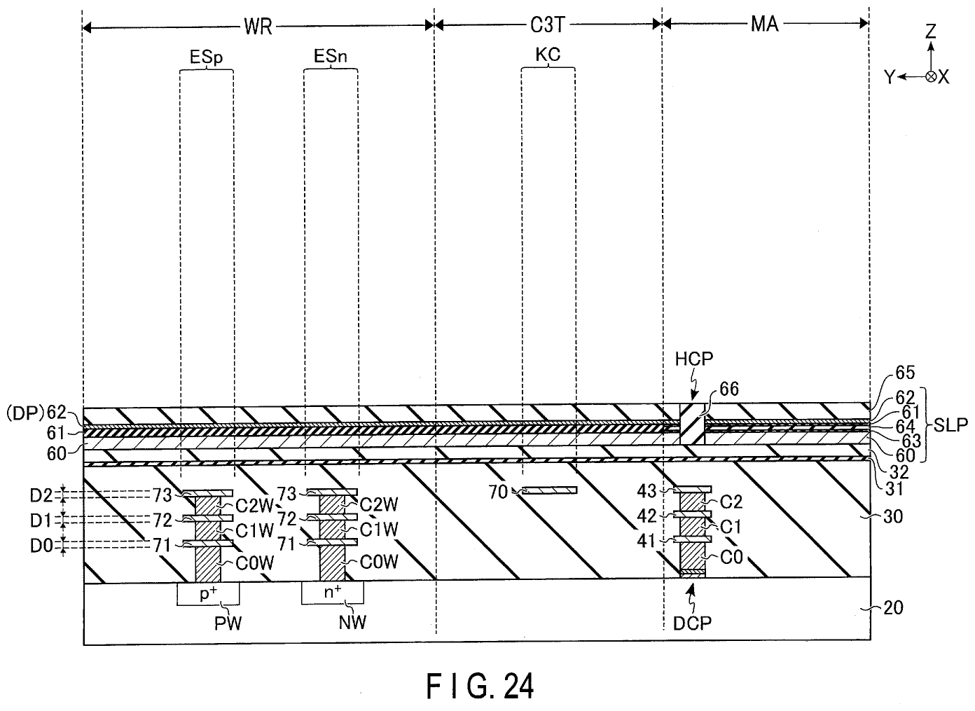

Subsequently, by a process of step S22, as illustrated in FIG. 24, an oxide film 66 is formed in the hole HCP. For example, the oxide film 66 is first formed in a manner to fill the hole HCP. Thereafter, by executing an etch-back process or CMP, a structure in which the oxide film 66 remains in the hole HCP is formed. Note that in the process of step S22, in a region not illustrated, the oxide film 66 is formed also in that part of the periphery of the core region CR, in which the layers provided at the same height as the source line portion SLP were removed by the process of step S21.

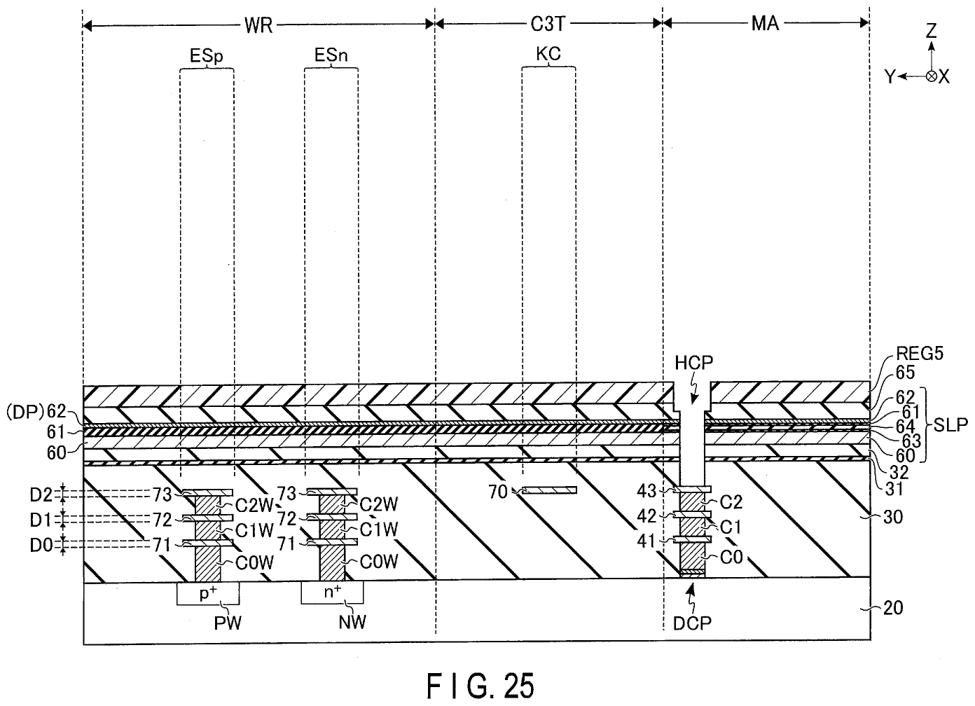

Next, by a process of step S23, as illustrated in FIG. 25, a bottom portion of the hole HCP is etched to reach the wiring layer D2. Specifically, at first, by photolithography, for example, a mask REG5 with an opening in a part overlapping the discharge-path contact portion DCP is formed. Then, an anisotropic etching process using the mask REG5 is executed, and the bottom portion of the hole HCP reaches the conductive layer 43 provided in the wiring layer D2. In other words, a surface of the conductive layer 43 is exposed in the bottom portion of the hole HCP. As the anisotropic etching process, for example, RIE is used. After this step is completed, the mask REG5 is removed.

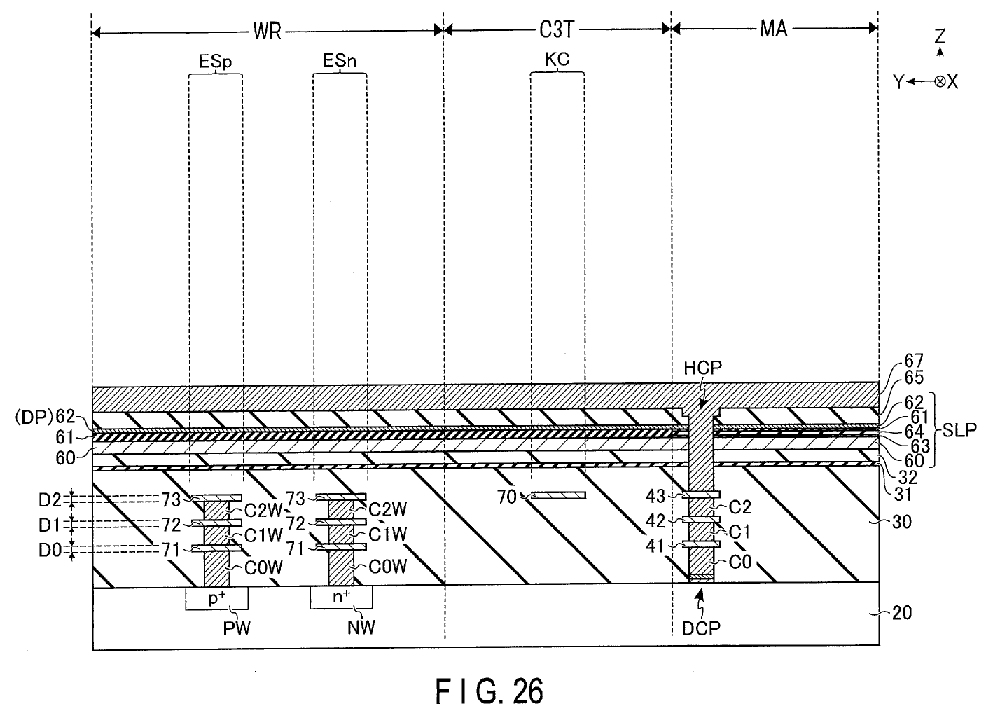

Subsequently, by a process of step S24, as illustrated in FIG. 26, a conductor 67 is formed. The conductor 67 is formed in a manner to fill at least the hole HCP. CVD, for example, is used to form the conductor 67.

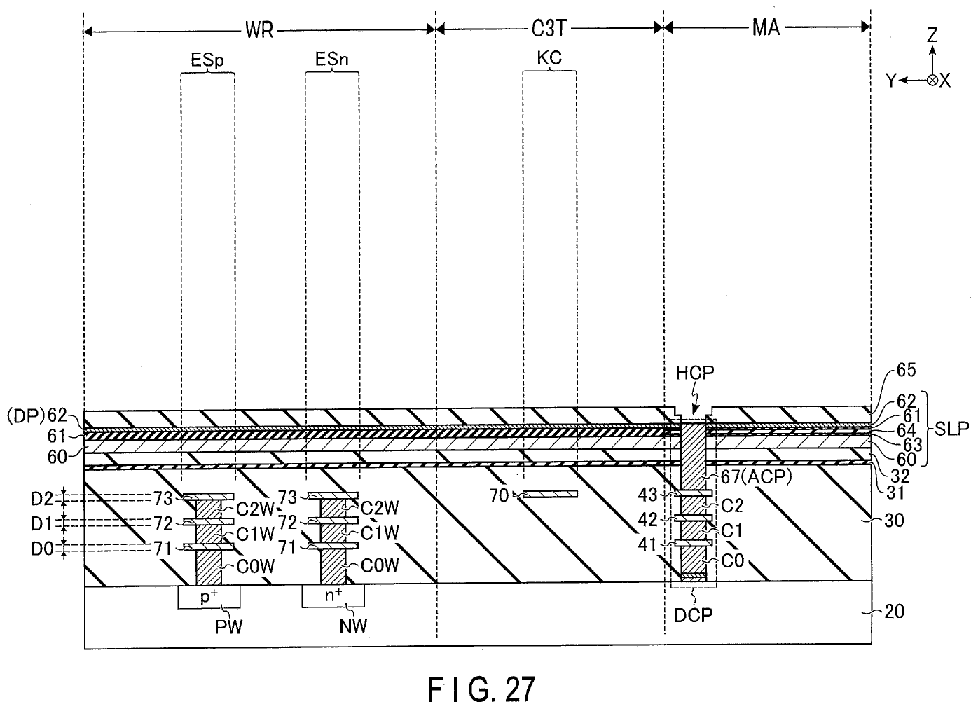

Next, by a process of step S25, as illustrated in FIG. 27, the conductor 67 outside the hole HCP is removed. An etch-back process, for example, is used to remove the conductor 67 outside the hole HCP.

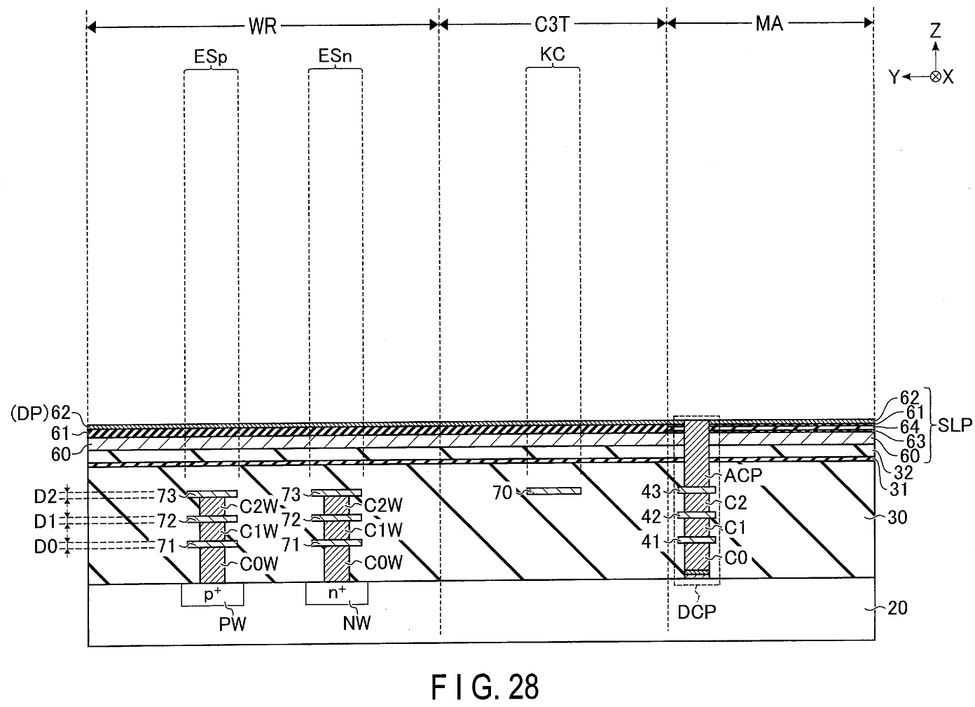

Subsequently, by a process of step S26, as illustrated in FIG. 28, the nitride film 65 is removed. In the removal of the nitride film 65, an isotropic etching process may be executed, an anisotropic etching process may be executed, or CMP may be executed.

Next, by a process of step S27, sacrificial members SM of a stacked wiring portion are formed. Specifically, insulating layers and sacrificial members SM are alternately stacked on the conductive layer 62. Thereafter, although illustration is omitted, a staircase structure of the sacrificial members SM is formed in each of the hookup regionsHA1 and HA2, for example, by repetition of a slimming process and an etching process. At this time, the sacrificial members SM formed in each of the contact region C3T and the wall region WR are removed. Then, a level difference formed by the staircase structure of the sacrificial members SM is filled with an insulating layer 36-1. Thereafter, a surface of the insulating layer 36-1 is planarized by, for example, CMP.

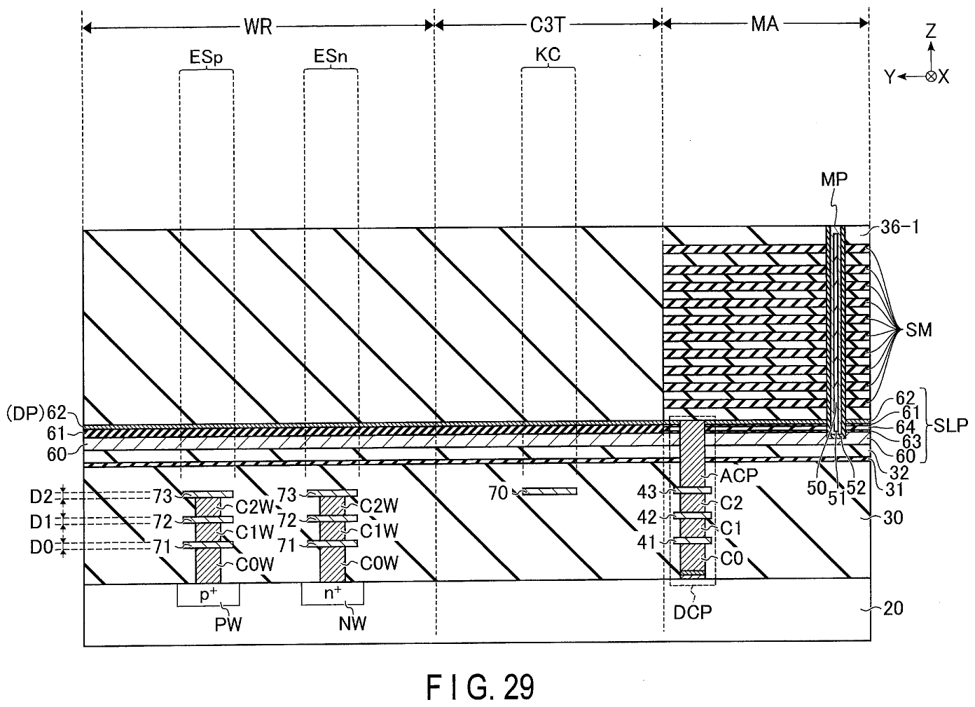

Subsequently, by a process of step S28, as illustrated in FIG. 29, the memory pillar MP is formed. Specifically, at first, by photolithography or the like, a mask with an opening in a region corresponding to the memory pillar MP is formed. By anisotropic etching using the mask, a hole is formed which penetrates the insulating layer 36-1, the stacked sacrificial members SM, the conductive layer 62, the insulating layer 61, the sacrificial member 64, and the insulating layer 63. At the bottom of the hole, a part of the conductive layer 60 is exposed. Then, the stacked film (i.e. the block insulating film 55, insulating film 54, and tunnel insulating film 53), the semiconductor layer 51, and the core member 50 are formed in the named order on the side surface and the bottom surface of the hole. Then, a part of the core member 50 provided in the upper part of the hole is removed, and the semiconductor layer 51 is formed in a portion where the core member 50 is removed.

Next, by a process of step S29, the slit SLT is formed. Specifically, although illustration is omitted, at first, a protective film covering an upper part of the memory pillar MP is formed. Hereinafter, a set of this protective film and the insulating layer 36-1 is referred to as “insulating layer 36-2”. Then, by photolithography or the like, a mask is formed in which a region corresponding to the slit SLT is opened. By an anisotropic etching process using the mask, the slit SLT is formed which divides the insulating layer 36-2, the stacked sacrificial members SM, the conductive layer 62, and the insulating layer 61. At the bottom portion of the slit SLT, the sacrificial member 64 is exposed.

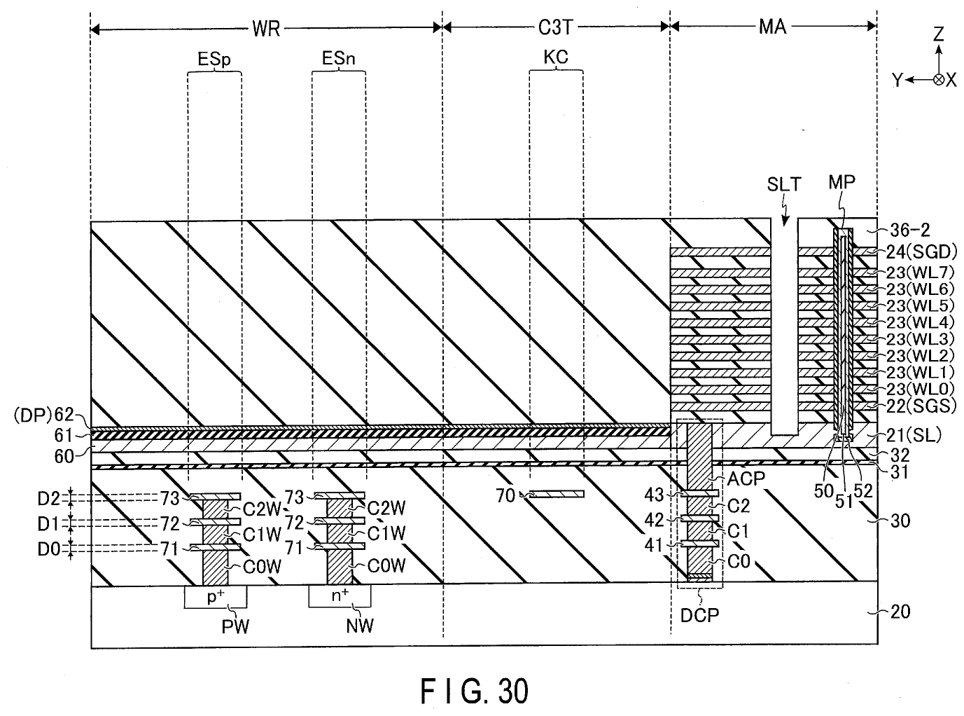

Next, by a process of step S30, as illustrated in FIG. 30, a replacement process is executed. In the replacement process, a replacement process of the source line portion SLP and a replacement process of the stacked wiring lines are executed in order.

In the replacement process of the source line portion SLP, the sacrificial member 64 is selectively removed via the slit SLT, for example, by wet etching. Subsequently, for example, by wet etching, the insulating layers 61 and 63 of the source line portion SLP and a part of the stacked film 52 on the side surface of the memory pillar MP are selectively removed via the slit SLT. Then, a conductor (e.g. silicon) is buried in a space formed in the source line portion SLP. Thereby, the conductive layer 21 is formed by the conductor and the conductive layers 60 and 62, and the conductive layer 21 and the semiconductor layer 51 in the memory pillar MP are electrically connected.

In the replacement process of the stacked wiring lines, the stacked sacrificial members SM are selectively removed via the slit SLT by wet etching with hot phosphoric acid or the like. Then, a conductor is buried in a space from which the sacrificial members SM have been removed, via the slit SLT. For example, CVD is used for formation of the conductor in this manufacturing step. Thereafter, the conductor formed inside the slit SLT is removed by an etch-back process, and the conductor formed in the adjacent wiring layer is separated. Thereby, the conductive layer 22 functioning as the select gate line SGS, the conductive layers 23 each functioning as the word line WL, and the conductive layer 24 functioning as the select gate line SGD are formed. The conductive layers 22 to 24 formed in this step may contain a barrier metal. In this case, in the formation of the conductor after the removal of the sacrificial members SM, for example, a film of titanium nitride is formed as a barrier metal, and then tungsten is formed.

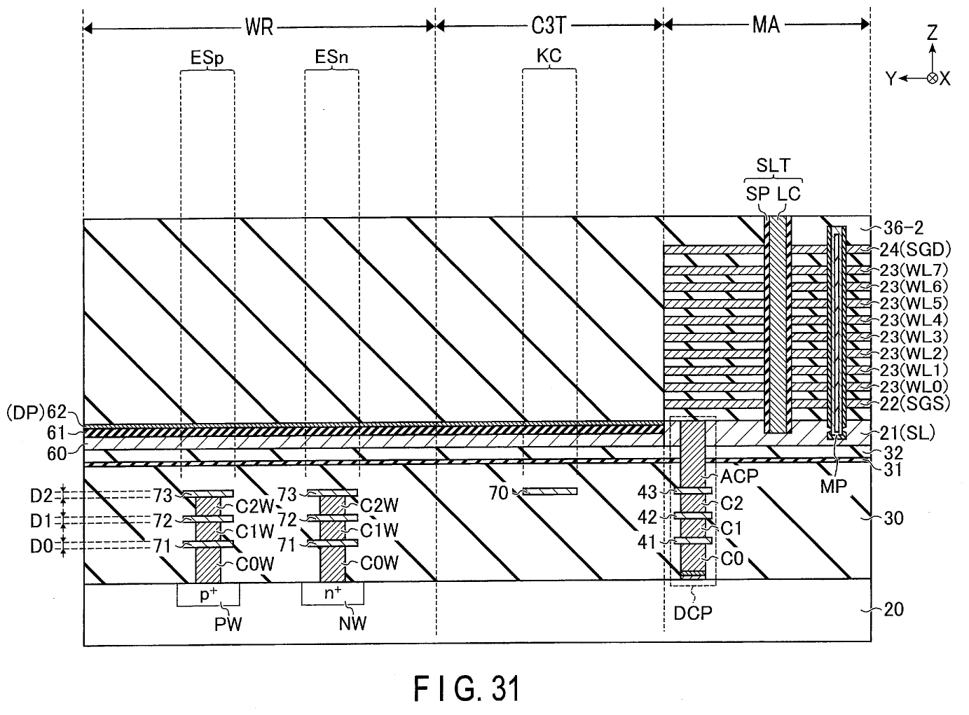

Next, by a process of step S31, as illustrated in FIG. 31, spacers SP and the contact LC are formed in the slit SLT. Specifically, at first, an insulating film corresponding to the spacers SP is formed by CVD or the like. The insulating film is formed not only on the side surfaces of the slit SLT but also on the bottom portion of the slit SLT. Subsequently, an etch-back process is executed, and the insulating film formed on the bottom portion of the slit SLT is removed. Thereby, the conductive layer 21 is exposed at the bottom portion of the slit SLT. Then, a conductor is buried in the slit SLT, and the conductor outside the slit SLT is removed. The conductor formed in the slit SLT corresponds to the contact LC. Thereafter, when an insulating layer is formed on the insulating layer 36-2, the structure of the insulating layer 36 illustrated in FIG. 11 is formed.

Subsequently, by a process of step S32, slits are formed in the wall region WR and the dividing portion KC. Specifically, by photolithography or the like, a mask is formed in which a region corresponding to the dividing portion KC, a region corresponding to the sealing member ESn, and a region corresponding to the sealing member ESp are opened. By an anisotropic etching process using the mask, the slit is formed in each of the region corresponding to the dividing portion KC, the region corresponding to the sealing member ESn and the region corresponding to the sealing member ESp. The slit divides the insulating layer 36, conductive layer 62, insulating layer 61, conductive layer 60, insulating layers 32 and 31, and a part of the insulating layer 30, and a surface of the conductive layer 70 or 73 is exposed at the bottom portion of each slit.

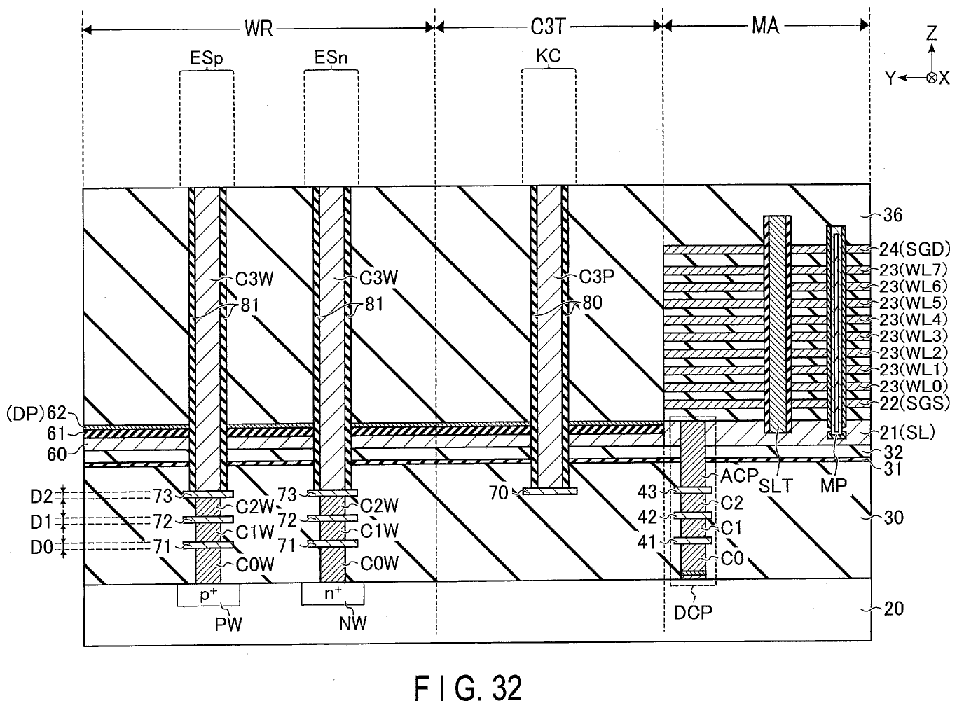

Next, by a process of step S33, as illustrated in FIG. 32, spacers 80 and 81 and contacts C3P and C3W are formed in the slits formed in step S32. Specifically, at first, an insulating film corresponding to the spacers 80 and 81 is formed by CVD or the like. The insulating film is formed not only on side surfaces, but also on a bottom portion, of each of the slits formed in step S32. Subsequently, an etch-back process is executed, and the insulating film formed on the bottom portion of each of the slits is removed. Thereby, the conductive layer 70 or 73 is exposed at the bottom portions of the slits. Then, a conductor is buried in each of the slits, and the conductor outside the slits is removed. The conductor formed in the slit in the wall region WR corresponds to the contact C3W. The conductor formed in the slit in the contact region C3T corresponds to the contact C3P.

By the above-described manufacturing steps, the contact ACP and the memory cell array 10 are formed. In addition, the structure is formed in which the sealing members ESn and ESp are formed and the conductive layers 60 and 62 corresponding to the conductive portion DP are divided by the spacers 80. Note that the above-described manufacturing steps are merely examples, another process may be inserted between the manufacturing steps, and the order of manufacturing steps may be changed as far as no problem will occur.

### [1-3] Advantageous Effects of the First Embodiment

According to the semiconductor memory device 1 of the first embodiment described above, a yield of the semiconductor memory device 1 can be improved. Hereinafter, the details of advantageous effects of the semiconductor memory device 1 according to the first embodiment will be described.

In a manufacturing process of a semiconductor memory device in which memory cells are three-dimensionally stacked, for example, a memory hole is formed in a structure in which sacrificial members and insulating members are alternately stacked, and a semiconductor member and the like corresponding to the memory cell and the like are formed in the memory hole. In an etching process of forming the memory hole, positive charge is accumulated in the bottom portion of the memory hole as the etching progresses, and a conductor (e.g. the source line SL) reached by the bottom portion of the memory hole may be positively charged. Then, a bias difference between the positively charged conductor and the negatively charged wafer becomes large, and arcing due to the bias difference may occur between the conductor and the wafer. Such arcing can occur, in particular, during processing of high aspect ratio memory holes and slits.

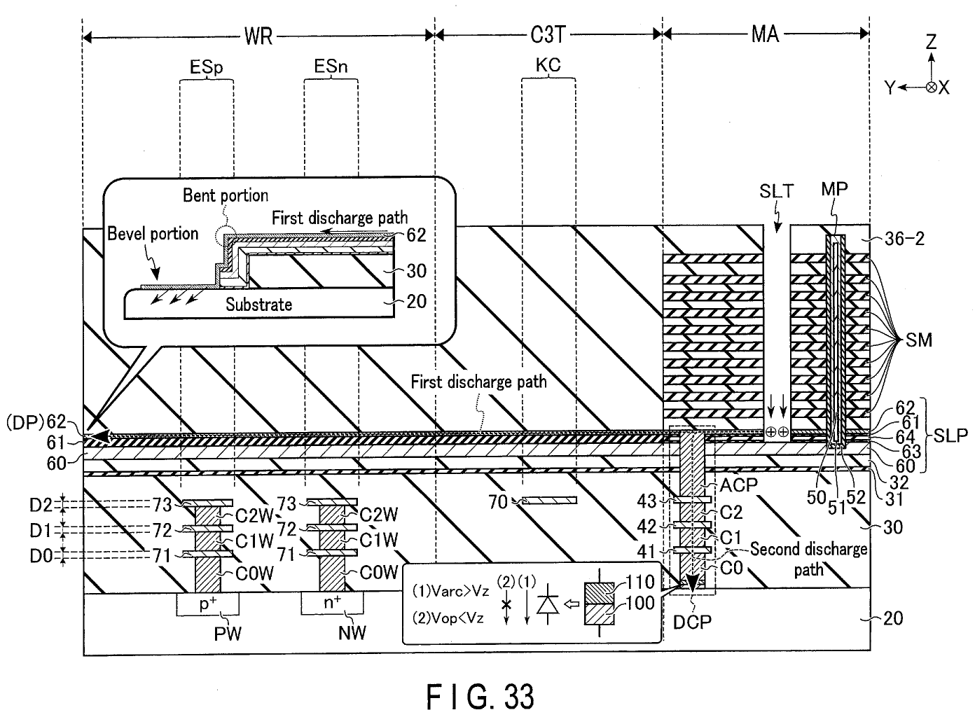

By contrast, the semiconductor memory device 1 according to the first embodiment includes at least one kind of discharge path in the high aspect ratio etching process, and suppresses the occurrence of arcing. FIG. 33 is a cross-sectional view illustrating an example of cross-sectional structure during manufacturing of the semiconductor memory device 1 according to the first embodiment, and illustrates a case in which positive charge occurs in the bottom portion of the slit SLT at a time of forming the slit SLT. As illustrated in FIG. 33, the semiconductor memory device 1 according to the first embodiment includes two kinds of discharge paths (first and second discharge paths) in the high aspect ratio etching process.

The first discharge path is a portion (conductive portion DP) in which the conductive layer 62 in the source line portion SLP and the conductive layer 62 in the kerf region KR are electrically connected. The conductive portion DP is provided to be in contact with, for example, a bevel portion of the wafer (semiconductor substrate 20). Thereby, in the high aspect ratio etching process, for example, the positive charge accumulated in the bottom portion of the slit SLT can be discharged to the semiconductor substrate 20 via the conductive portion DP that is in contact with the bevel portion of the wafer. Note that when the conductive layer 62 in the kerf region KR and the conductive layer 62 in the core region CR (e.g. memory region MA) have the same potential, or when the conductive layers 62 in the core regions CR have the same potential, the semiconductor memory device 1 cannot be controlled. For this reason, after the countermeasure against arcing is no longer required (for example, after the processing of the slit SLT), the conductive layer 62 in the kerf region KR and the conductive layer 62 in the core region CR, or the conductive layers 62 in the core regions CR, are electrically divided from each other by the dividing portion KC.

The second discharge path is a portion (discharge-path contact portion DCP) in which the conductive layers 60 and 62 in the source line portion SLP are electrically connected to the semiconductor substrate 20 in the core region CR (e.g. memory region MA). The discharge-path contact portion DCP includes the contact C0 including a diode structure (semiconductor layers 100 and 110) which is connected in a reverse direction from the conductive layer 62 side toward the semiconductor substrate 20. In the high aspect ratio etching process, a voltage Varc, which is applied to the diode provided in the discharge-path contact portion DCP is greater than a breakdown voltage Vz ((1) Varc >Vz). Thereby, in the high aspect ratio etching process, for example, the positive charge accumulated in the bottom portion of the slit SLT can be discharged to the semiconductor substrate 20 via the diode formed in the discharge-path contact portion DCP. Note that, although the source line SL and the semiconductor substrate 20 are connected via the discharge-path contact portion DCP, an operational voltage Vop of the semiconductor memory device 1 is less than the breakdown voltage Vz ((2) Vop <Vz). Specifically, the diode in the discharge-path contact portion DCP is in an OFF state during the operation of the semiconductor memory device 1, and shuts off the current path between the source line SL and the semiconductor substrate 20. Thus, the connection between the source line SL and the semiconductor substrate 20 via the discharge-path contact portion DCP may remain at a time of shipment of the semiconductor memory device 1.

As has been described above, the semiconductor memory device 1 according to the first embodiment includes, in the high aspect ratio etching process, the first discharge path via the bevel portion of the wafer, and the second discharge path via the discharge-path contact portion DCP, between the source line SL and the semiconductor substrate 20. As a result, in the high aspect ratio etching process, the semiconductor memory device 1 according to the first embodiment can suppress a bias difference between the source line SL and the semiconductor substrate 20, and can suppress the occurrence of arcing. Therefore, the semiconductor memory device 1 according to the first embodiment can suppress the occurrence of a defect due to the influence of arcing, and can improve the yield.

Note that when the conductive layer 62 is formed in contact with the bevel portion of the wafer, the conductive layer 62 includes a bent portion in the peripheral portion of the wafer. There is a possibility that such a bent portion of the conductive layer 62 is divided when over-polishing occurs in a planarization step included in the manufacturing process of the semiconductor memory device 1. In this manner, there is a possibility that the first discharge path cannot be used to suppress arcing. On the other hand, the discharge-path contact portion DCP used in the second discharge path is provided near the core region CR (memory region MA), which is located more inward than the wall region WR, and thus the discharge path cannot be divided due to over-polishing in the planarization step. Therefore, it suffice that the semiconductor memory device 1 according to the first embodiment includes at least the discharge-path contact portion DCP as at least one kind of discharge path.

Specifically, in the first embodiment, the case was described in which the occurrence of arcing is suppressed by using the first discharge path and the second discharge path. However, the first discharge path may be omitted. If the semiconductor memory device 1 utilizes at least the structure relating to the second discharge path, the occurrence of arcing can be suppressed. Furthermore, with the omission of the first discharge path, the cost relating to the formation of the dividing portion KC can be held down, and the manufacturing cost of the semiconductor memory device 1 can be held down.

In addition, the discharge-path contact portion DCP may be disposed in the kerf region KR. With the discharge-path contact portion DCP being provided in each of the core region CR and the kerf region KR, both the arcing occurring in the core region CR and the arcing occurring in the kerf region. KR can be suppressed. In this case, since the connection between the conductive layer 62 in the core region CR and the conductive layer 62 in the kerf region KR is not indispensable, the dividing portion KC can be omitted.

Furthermore, as described above, the discharge-path contact portion DCP in the first embodiment includes, in the contact C0, the semiconductor layers 100 and 110 functioning as the diode. Thus, in the discharge-path contact portion DCP in the first embodiment, since the reversely connected diode between the source line SL and the semiconductor substrate 20 is formed as the second discharge path, the area of installation can be reduced and the junction capacitance can be reduced, compared to the case where an impurity diffusion region is formed in the semiconductor substrate 20. The reduction in junction capacitance can suppress a leak current due to a junction, and can improve the operational characteristics of the semiconductor memory device 1.

### [1-4] Modifications of the First Embodiment

The semiconductor memory device 1 according to the above-described first embodiment can variously be modified. Hereinafter, a first modification and a second modification of the first embodiment will be described with respect to different points from the first embodiment.

### [1-4-1] First Modification of the First Embodiment

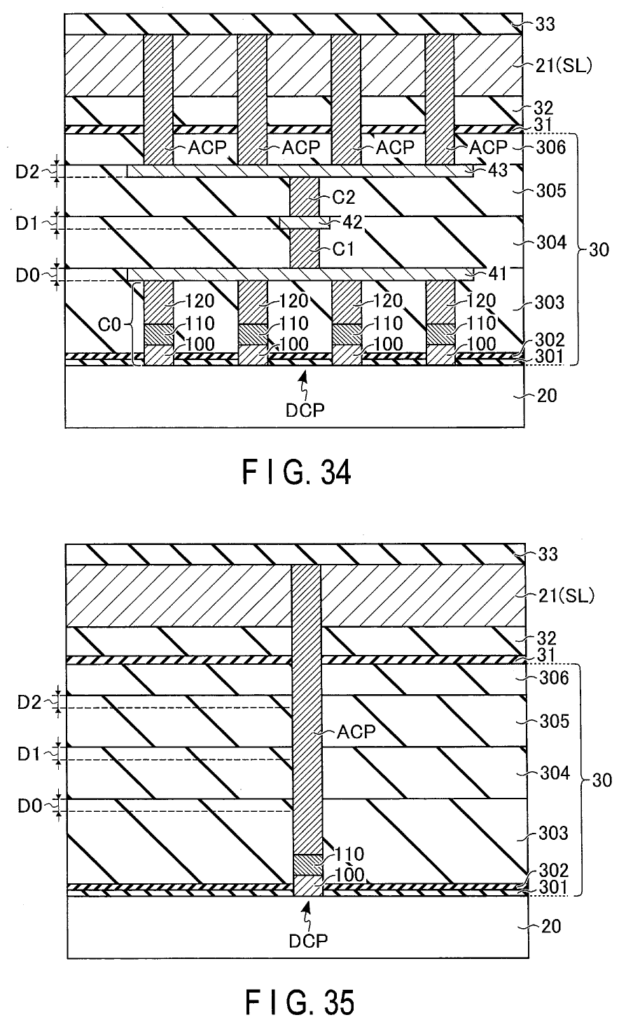

FIG. 34 is a cross-sectional view illustrating an example of cross-sectional structure including a discharge-path contact portion DCP of a semiconductor memory device 1 according to the first modification of the first embodiment, and illustrates one discharge-path contact portion DCP. As illustrated in FIG. 34, in the discharge-path contact portion DCP, the numbers of contacts and wiring layers, which serve as a relay between the conductive layer 21 (source line SL) and the semiconductor substrate 20, may vary from layer to layer. In the present example, the semiconductor substrate 20 and the conductive layer 41 are connected by four contacts C0, the conductive layer 41 and the conductive layer 42 are connected by one contact C1, the conductive layer 42 and the conductive layer 43 are connected by one contact C2, and the conductive layer 43 and the conductive layer 21 are connected by four contacts.

In this case, too, the semiconductor memory device 1 according to the first modification of the first embodiment can obtain the same advantageous effects as in the first embodiment. In addition, the increase in the number of contacts, which connect the semiconductor substrate 20 and the conductive layer 21, can enhance the efficiency with which the discharge-path contact portion DCP discharges the positive charge accumulated in the conductive layer 21 to the semiconductor substrate 20. Furthermore, since the number of contacts used to connect the semiconductor substrate 20 and the conductive layer 21 is decreased in a specific wiring layer, the difficulty of wiring layout in the specific wiring layer can be lowered. Note that the numbers of contacts C0, C1, C2 and ACP, which are provided in one discharge-path contact portion DCP, can freely be designed.

### [1-4-2] Second Modification of the First Embodiment

FIG. 35 is a cross-sectional view illustrating an example of cross-sectional structure including a discharge-path contact portion DCP of a semiconductor memory device 1 according to the second modification of the first embodiment, and illustrates one discharge-path contact portion DCP. As illustrated in FIG. 35, in the discharge-path contact portion DCP, the connection between the semiconductor substrate 20 and the conductive layer 21 may be achieved by one contact ACP. Specifically, that part of the discharge-path contact portion DCP, which excludes the PN-junction diode, may be formed of one conductive member extending in the Z direction. In this case, the semiconductor layers 100 and 110 are formed in a bottom portion of the contact ACP. The structure of the semiconductor layers 100 and 110 formed in the bottom portion of the contact ACP is the same as the structure of the semiconductor layers 100 and 110 provided in the contact C0 of the discharge-path contact portion DCP described in the first embodiment.

In this case, too, the semiconductor memory device 1 according to the second modification of the first embodiment can obtain the same advantageous effects as in the first embodiment.

### [2] Second Embodiment

A semiconductor memory device 1 according to a second embodiment has such a structure that PN-junction diodes are formed in contact parts between a contact portion connected to the semiconductor substrate 20, and the conductive layers 60 and 62 included in the source line SL. Hereinafter, the semiconductor memory device 1 according to the second embodiment will be described with respect to different points from the first embodiment.

### [2-1] Structure of Semiconductor Memory Device 1 in Wiring Layer Including Source Line SL

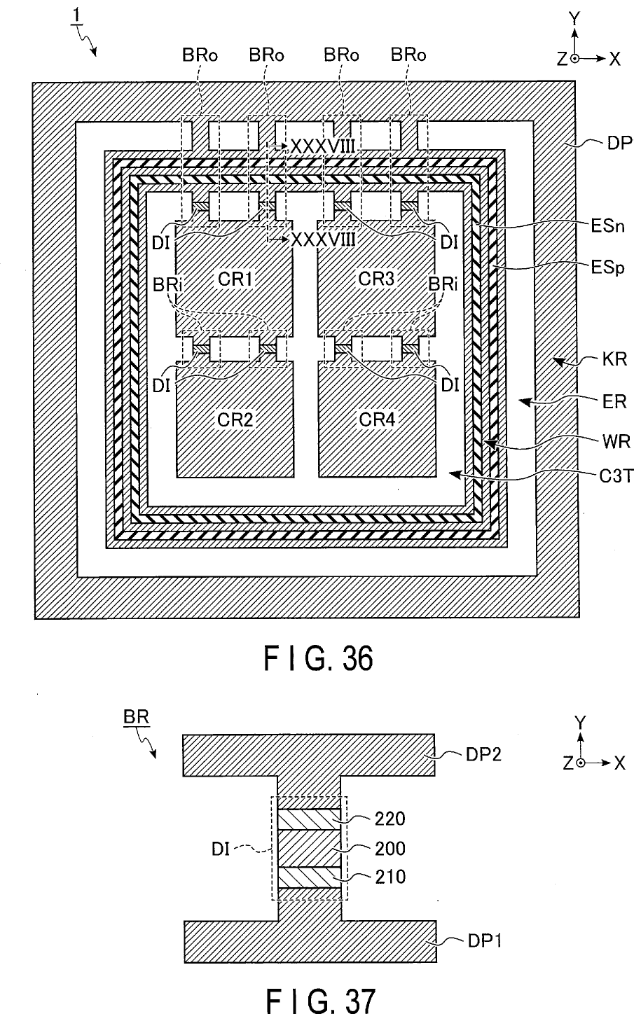

FIG. 36 is a plan view illustrating an example of a plan layout in a wiring layer including the source line SL of the semiconductor memory device according to the second embodiment. FIG. 36 illustrates the same area as the plan layout of the semiconductor memory device 1 according to the first embodiment illustrated in FIG. 3. As illustrated in FIG. 36, the semiconductor memory device 1 according to the second embodiment has such a structure that in the semiconductor memory device 1 according to the first embodiment, the plurality of dividing portions KC are replaced with a plurality of diode portions DI, respectively.

The plurality of diode portions DI are provided to overlap the plurality of bridge portions BR, and divide the conductive portions DP of the bridge portions BR. In the present example, the diode portions DI are provided in a part where the bridge portion BRo and the contact regions C3T overlap and in a part where the bridge portion BRi and the contact region C3T overlap, respectively. The conductive portion DP, which is in contact with one side of the diode portion DI, and the conductive portion DP, which is in contact with the other side of the diode portion DI, are connected to the semiconductor substrate 20 via PN-junction diodes each connected in a reverse direction. The number of diode portions DI, which are provided in one bridge portion BR, may be one or more.

FIG. 37 is a plan view illustrating an example of a plan layout of the bridge portion BR in the semiconductor memory device 1 according to the second embodiment, and illustrates a common structure between the bridge portions BRo and BRi. As illustrated in FIG. 37, the diode portion DI included in the bridge portion BR includes a plug (contact) 200 and semiconductor layers 210 and 220. Note that a conductive portion DP1 corresponds to the conductive portion DP provided in one of mutually neighboring regions which are connected by the bridge portion BR illustrated. A conductive portion DP2 corresponds to the conductive portion DP provided in the other of the mutually neighboring regions connected by the bridge portion BR illustrated. The conductive portion DP corresponds to the conductive layer 21, or the set of the conductive layers 60 and 62.

The plug 200 is provided between the conductive portion DP1 and the conductive portion DP2. The plug 200 includes a portion extending in the Z direction, and is electrically connected to the semiconductor substrate 20.

The semiconductor layer 210 is provided between the conductive portion DP1 and the plug 200, and is in contact with each of the conductive portion DP1 and the plug 200. In other words, the plug 200 is connected to the conductive portion DP1 via the semiconductor layer 210. The semiconductor layer 210 is P-type polysilicon containing P-type impurities. The conductive portion DP1 is, for example, N-type polysilicon containing N-type impurities. Thus, a PN junction is formed in a contact part between the conductive portion DP1 and the semiconductor layer 210. In addition, the contact part between the conductive portion DP1 and the semiconductor layer 210 functions as a PN-junction diode connected in a reverse direction from the conductive portion DP1 toward the plug 200.

The semiconductor layer 220 is provided between the conductive portion DP2 and the plug 200, and is in contact with each of the conductive portion DP2 and the plug 200. In other words, the plug 200 is connected to the conductive portion DP2 via the semiconductor layer 220. The semiconductor layer 220 is P-type polysilicon containing P-type impurities. The conductive portion DP2 is, for example, N-type polysilicon containing N-type impurities. Thus, a PN junction is formed in a contact part between the conductive portion DP2 and the semiconductor layer 220. In addition, the contact part between the conductive portion DP2 and the semiconductor layer 220 functions as a PN-junction diode connected in a reverse direction from the conductive portion DP2 toward the plug 200.

Note that the concentration of N-type impurities doped in the conductive layers 60 and 62 used for the source line SL is preferably, for example, less than 10²⁰ (atoms/cm³). The concentration of P-type impurities doped in the semiconductor layers 210 and 220 is preferably 10²⁰ (atoms/cm³) or more. The PN-junction diode formed with this structure can increase a depletion layer width, and can increase a breakdown voltage. Note that if the depletion layer width of the PN-junction diode can appropriately be designed by an impurity concentration gradient formed by the semiconductor layers 210 and 220 and conductive layers 60 and 62, each of the semiconductor layers 210 and 220 and conductive layers 60 and 62 may have other concentration designs. The plug 200 may be connected to an impurity diffusion region formed in a surface portion of the semiconductor substrate 20. The semiconductor layers 210 and 220 may be treated as structures included in the conductive portions DP1 and DP2 (conductive layers 60 and 62), respectively.

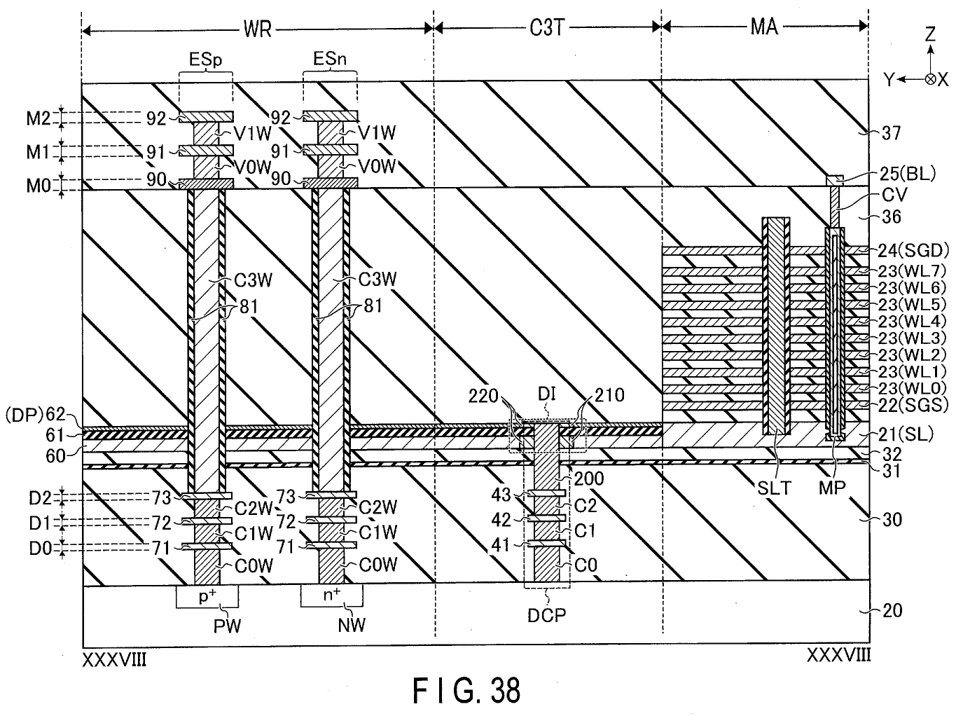

FIG. 38 is a cross-sectional view taken along a line XXXVIII-XXXVIII of FIG. 36, FIG. 38 illustrating an example of cross-sectional structure in the memory region MA, the contact region C3T and the wall region WR of the semiconductor memory device 1 according to the second embodiment. As illustrated in FIG. 38, the semiconductor memory device 1 according to the second embodiment has such a structure that, in the semiconductor memory device 1 according to the first embodiment, the dividing portion KC is omitted and replaced with the diode portion DI.

The diode portion DI is connected to the discharge-path contact portion DCP. The discharge-path contact portion DCP in the second embodiment includes the contacts C0, C1 and C2, the conductive layers 41, 42 and 43, and the plug (contact) 200. The arrangement of the contacts C0, C1 and C2 and conductive layers 41, 42 and 43 is similar to the arrangement in the discharge-path contact portion DCP in the first embodiment.

The plug 200 is provided on the conductive layer 43. The plug 200 penetrates, for example, the conductive layer 62, insulating layer 61, conductive layer 60, insulating layers 32 and 31, and a part of the insulating layer 30. The side surface of the plug 200 is in contact with the semiconductor layers 210 and 220 and the insulating layer 61 at the height at which the conductive layer 21 is provided. The upper surface of the plug 200 is aligned with, for example, the upper surface of the conductive layer 62.

In the present example, the PN-junction diode, which is formed by the semiconductor layer 210 and the conductive layers 60 and 62 in the contact region C3T, is formed between the plug 200 and the memory region MA. The PN-junction diode, which is formed by the semiconductor layer 220 and the conductive layers 60 and 62 in the contact region C3T, is formed between the plug 200 and the wall region WR.

### [2-2] Manufacturing Method of Semiconductor Memory Device 1

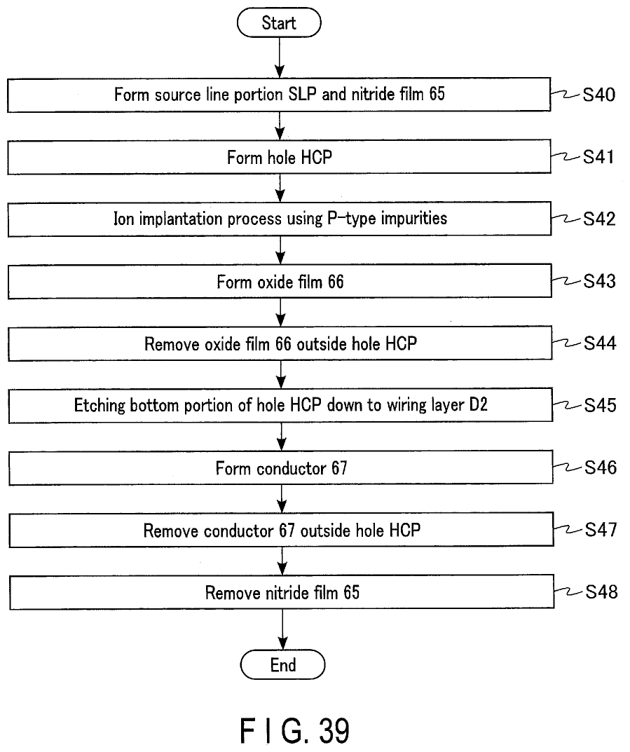

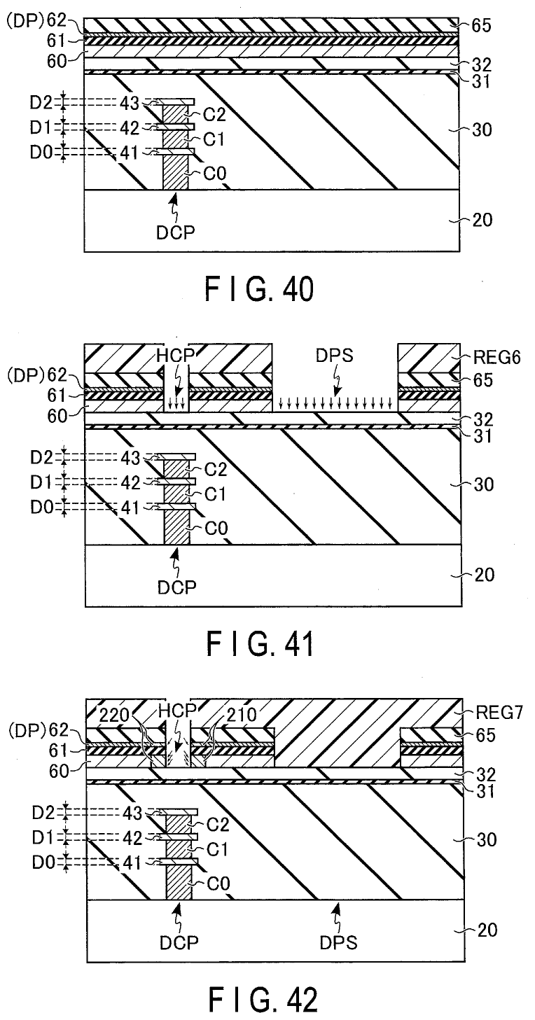

FIG. 39 is a flowchart illustrating an example of a method for manufacturing the semiconductor memory device 1 according to the second embodiment, and illustrates an example of manufacturing steps relating to the formation of the diode portion DI. FIGS. 40 to 48 are cross-sectional views illustrating an example of cross-sectional structure during manufacturing of the semiconductor memory device 1 according to the second embodiment. Each of FIG. 40 to FIG. 48 illustrates a region where one discharge-path contact portion DCF and one slit DPS are formed. The slit DPS corresponds to the dividing portion (core region dividing portion) of the conductive layer 62, insulating layer 61 and conductive layer 60, which is mentioned in the notes in connection with step S21 described in the first embodiment. As illustrated in FIG. 39, the formation process of the diode portion DI includes steps S40 to S48.

To start with, by a process of step S40, as illustrated in FIG. 40, the source line portion SLP, a set of the conductive layer 62, insulating layer 61 and conductive layer 60, which is provided at the same height as the source line portion SLP, and the nitride film 65 which is provided thereon, are formed. The process of step S40 is the same as, for example, the process of step S20 described in the first embodiment.

Next, by a process of step S41, as illustrated in FIG. 41, a hole HCP penetrating the set of the conductive layer 62, insulating layer 61 and conductive layer 60 is formed. The process of step S41 is the same as, for example, the process of step S21 described in the first embodiment. FIG. 41 illustrates a mask REG6 in which a part corresponding to the hole HCP and a part corresponding to the slit DPS are opened. The slit DPS corresponds to a region which divides the set of the conductive layer 62, insulating layer 61 and conductive layer 60 at the periphery of the core region CR. The hole HCP and slit DPS divide each of the nitride film 65, conductive layer 62, insulating layer 61 and conductive layer 60, and a surface of the insulating layer 32 is exposed at bottom portions of the hole HCP and slit DPS. After the hole HCP and slit DPS are formed, the mask REG6 is removed.

Subsequently, by a process of step 542, as illustrated in FIG. 42, an ion implantation process using P-type impurities is executed. Specifically, at first, by photolithography, a mask REG7 with an opening in a part of the hole HCP is formed. Then, using the mask REG7, an ion implantation process using P-type impurities is executed, and the P-type impurities are implanted in each of the conductive layers 60 and 62 which are exposed on the side wall of the hole HCP. One side surface of the part, where the P-type impurities are implanted in the conductive layers 60 and 62, functions as the semiconductor layer 210, and the other side surface thereof functions as the semiconductor layer 220. In other words, for example, by the P-type impurities being implanted in the N-type conductive layer (semiconductor layer) formed in the set of layers at the same height as the source line portion SLP, PN-junction diodes corresponding to the diode portion DI are formed on the memory region MA side and the wall region WR side, respectively. After the ion implantation process is completed, the mask REG7 is removed.

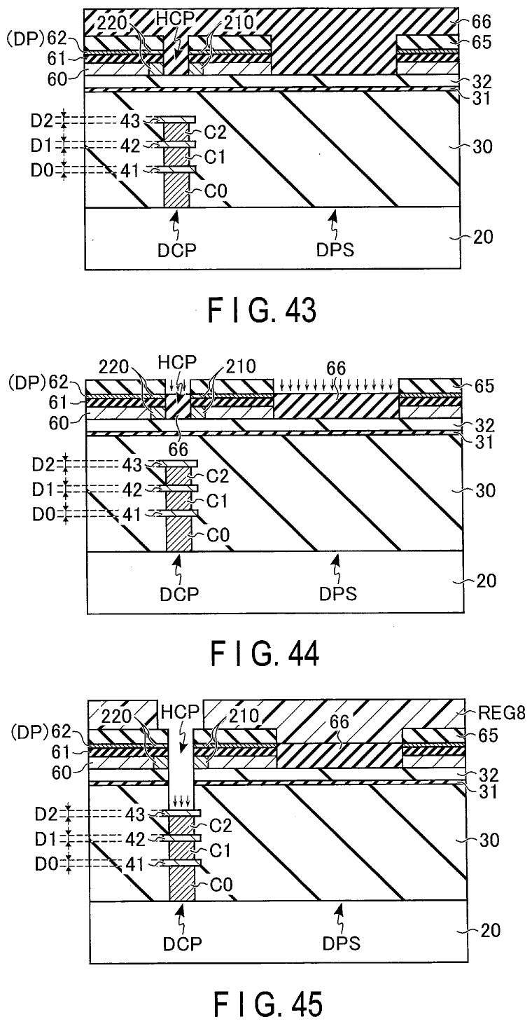

Next, by a process of step S43, as illustrated in FIG. 43, an oxide film 66 is formed. The oxide film 66 is formed in a manner to fill the hole HCP and the slit DPS.

Subsequently, by a process of step S44, as illustrated in FIG. 44, an etch-back process is executed on the oxide film 66. If the process of step S44 is executed, the oxide film 66 formed on the upper surface of the nitride film 65 is removed. Then, for example, the upper surface of the oxide film 66 formed in the hole HCP, the upper surface of the oxide film 66 formed in the slit DPS, and the upper surface of the conductive layer 62 are processed to be aligned. Note that the process of step S43 and S44 is similar to, for example, the process of step S22 described in the first embodiment.

Next, by a process of step S45, as illustrated in FIG. 45, the bottom portion of the hole HCP is etched to reach the wiring layer D2. The process of step S45 is similar to, for example, the process of step S23 described in the first embodiment. A mask REG8 illustrated is provided such that a part overlapping the hole HCP is opened. In addition, by an anisotropic etching process using the mask REG8, the surface of the conductive layer 43 of the discharge-path contact portion DCP is exposed at the bottom portion of the hole HCP. After the process of step S45 is completed, the mask REG8 is removed.

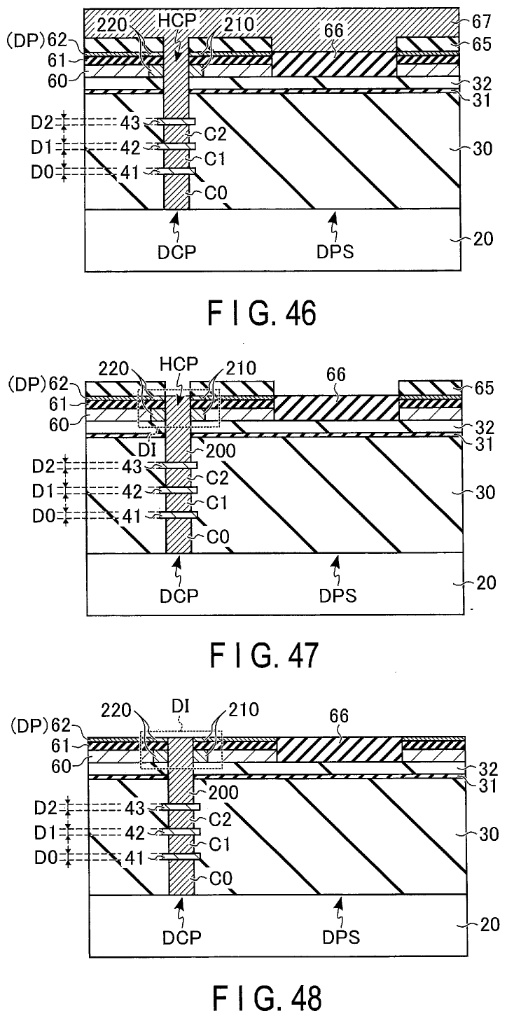

Subsequently, by a process of step S46, as illustrated in FIG. 46, a conductor 67 is formed. The process of step S46 is similar to, for example, the process of step S24 described in the first embodiment. The conductor 67 is formed in a manner to fill the hole HCP.

Next, by a process of step S47, as illustrated in FIG. 47, the conductor 67 outside the hole HCP is removed. The process of step S47 is similar to, for example, the process of step S25 described in the first embodiment. By this process, a structure in which the conductor 67 remains in the hole HCP is formed. That part of the conductor 67, which remains in the hole HCP, corresponds to the plug (contact) 200. The plug 200 is in contact with each of the semiconductor layers 210 and 220.

Following the above, by a process of step S48, as illustrated in FIG. 48, the nitride film 65 is removed. The process of step S48 is similar to, for example, the process of step S26 described in the first embodiment.

By the above-described manufacturing steps, the diode portion DI is formed. Specifically, a structure is formed in which the PN-junction diode formed in the contact part between the conductive layers 60 and 62 and the semiconductor layer 210 is connected in a reverse direction to the plug 200. Similarly, a structure is formed in which the PN-junction diode formed in the contact part between the conductive layers 60 and 62 and the semiconductor layer 220 is connected in a reverse direction to the plug 200. Note that the above-described manufacturing steps are merely examples, and another process may be inserted between the manufacturing steps, and the order of manufacturing steps may be changed as far as no problem will occur.

### [2-3] Advantageous Effects of the Second Embodiment

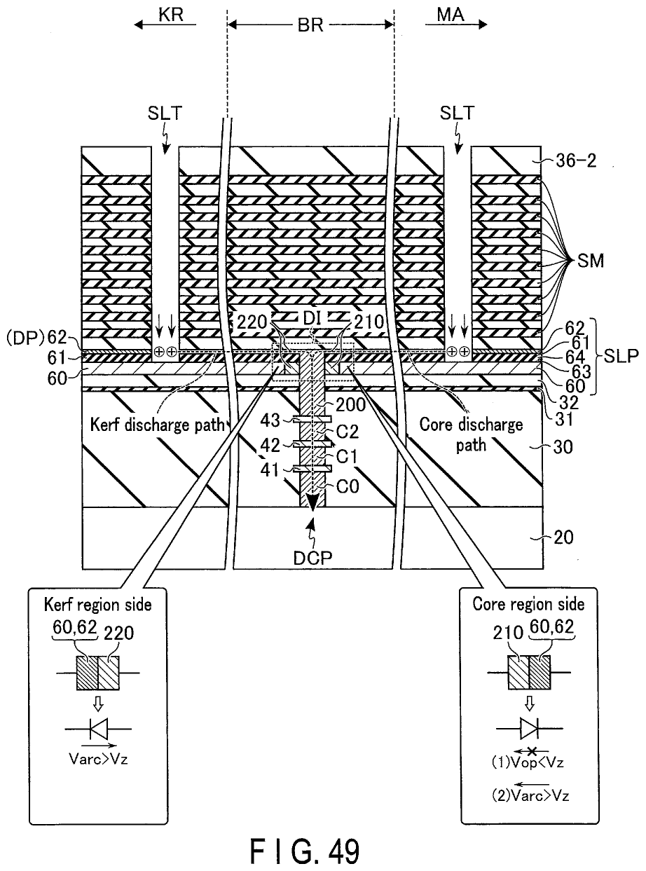

FIG. 49 is a cross-sectional view illustrating an example of cross-sectional structure during manufacturing of the semiconductor memory device 1 according to the second embodiment, and illustrates a case in which positive charge occurs in the bottom portions of the slits SLT at the time of forming the slits SLT. In addition, FIG. 49 illustrates a case in which the stacked structure of the sacrificial members SM and insulating layers is also formed in both of the bridge portion BR and the kerf region KR, and the slit SLT is also formed in the kerf region KR. As illustrated in FIG. 49, the semiconductor memory device 1 according to the second embodiment has such a structure that, in the bridge portion BR, the discharge-path contact portion DCP is provided in place of the dividing portion KC in the first embodiment. The discharge-path contact portion DCP includes the plug (contact) 200 which divides the layers provided at the same height as the source line portion SLP in the bridge portion BR, and is electrically connected to the conductive layers 60 and 62 included in the source line portion SLP.

Furthermore, in the semiconductor memory device 1 according to the second embodiment, the plug 200 in the discharge-path contact portion DCP is connected via the diode structure to the conductive layers 60 and 62 in the memory region MA and to the conductive layers 60 and 62 in the kerf region KR (the diode portion DI). Specifically, the connection part between the plug 200 of the discharge-path contact portion DCP and the conductive layers 60 and 62 includes the diode structure (the semiconductor layer 210 and conductive layers 60 and 62) which is connected in a reverse direction from the memory region MA side toward the plug 200, and the diode structure (the semiconductor layer 220 and conductive layers 60 and 62) which is connected in a reverse direction from the kerf region KR side toward the plug 200.

As a result, in the high aspect ratio etching process, the positive charge occurring in the kerf region KR flows into the discharge-path contact portion DCP via the diode structure on the kerf region KR side, and is discharged to the semiconductor substrate 20 (kerf discharge path). Similarly, in the high aspect ratio etching process, the positive charge occurring in the core region CR (memory region MA) flows into the discharge-path contact portion DCP via the diode structure on the memory region MA side, and is discharged to the semiconductor substrate 20 (core discharge path).

Thereby, like the first embodiment, in the high aspect ratio etching process, the semiconductor memory device 1 according to the second embodiment can suppress a bias difference between the source line SL and the semiconductor substrate 20, and can suppress the occurrence of arcing. Therefore, like the first embodiment, the semiconductor memory device 1 according to the second embodiment can suppress the occurrence of a defect due to the influence of arcing, and can improve the yield.

Note that, like the first embodiment, in the semiconductor memory device 1 according to the second embodiment, in the high aspect ratio etching process, the voltage Varc, which is applied to the diode structure on the core region CR side, is greater than the breakdown voltage Vz ((1) Varc >Vz), and the operational voltage Vop of the semiconductor memory device 1 is less than the breakdown voltage Vz ((2) Vop <Vz). Thus, in the semiconductor memory device 1 according to the second embodiment, the connection between the source line SL and the semiconductor substrate 20 via the discharge-path contact portion DCP may remain at a time of shipment of the semiconductor memory device 1.

### [2-4] Modifications of the Second Embodiment

The semiconductor memory device 1 according to the above-described second embodiment can variously be modified. Hereinafter, a first modification, a second modification, a third modification and a fourth modification of the second embodiment will be described with respect to different points from the second embodiment.

### [2-4-1] First Modification of the Second Embodiment

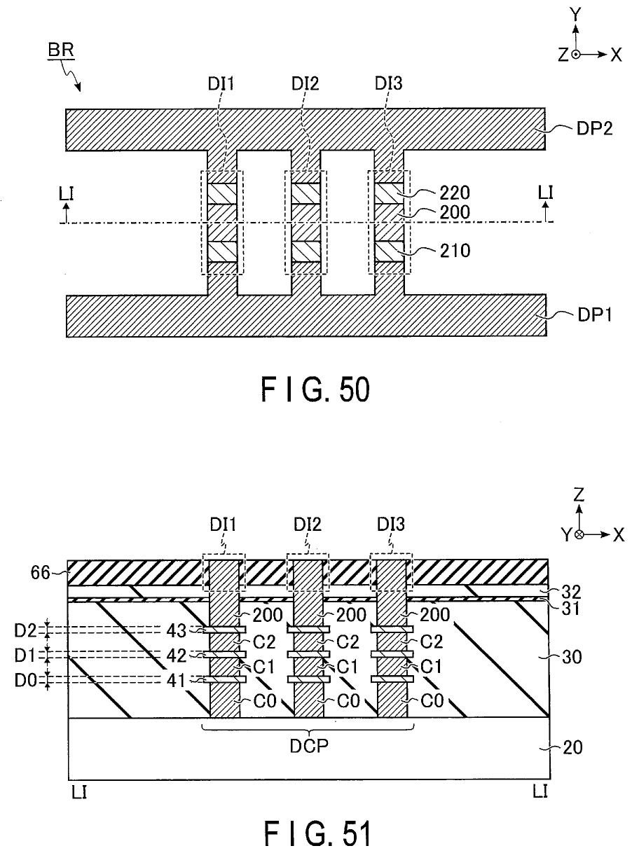

FIG. 50 is a plan view illustrating an example of a plan layout of a bridge portion in a semiconductor memory device according to a first modification of the second embodiment. As illustrated in FIG. 50, in the bridge portion BR, a plurality of diode portions DI may connect conductive portions DP1 and DP2 which neighbor each other. In this example, the bridge BR includes diode portions DI1, DI2 and DI3.

The structure of each of the diode portions DI1, DI2 and DI3 in the first modification of the second embodiment is the same as the structure of the diode portion DI described in the second embodiment. In addition, the semiconductor layer 210 of each of the diode portions DI1, DI2 and DI3 is connected to the conductive portion DP1, and the semiconductor layer 220 of each of the diode portions DI1, DI2 and DI3 is connected to the conductive portion DP2. Note that in the first modification of the second embodiment, the number of diode portions DI included in the bridge portion BR may be two or more. The diode portion DI in the first modification of the second embodiment may be regarded as a structure in which the diode portion DI described in the second embodiment is divided.

FIG. 51 is a cross-sectional view taken along a line LI-LI of FIG. 50, FIG. 51 illustrating an example of cross-sectional structure of a discharge-path contact portion DCP in the semiconductor memory device 1 according to the first modification of the second embodiment. As illustrated in FIG. 51, in the first modification of the second embodiment, each of the diode portions DI1, DI2 and DI3 has such a structure that the contact C0, conductive layer 41, contact C1, conductive layer 42, contact C2, conductive layer 43 and plug 200 are connected in the Z direction. In this case, too, the semiconductor memory device 1 according to the first modification of the second embodiment can obtain the same advantageous effects as in the second embodiment, and can improve the performance of the discharge-path contact portion DCP.

### [2-4-2] Second Modification of the Second Embodiment

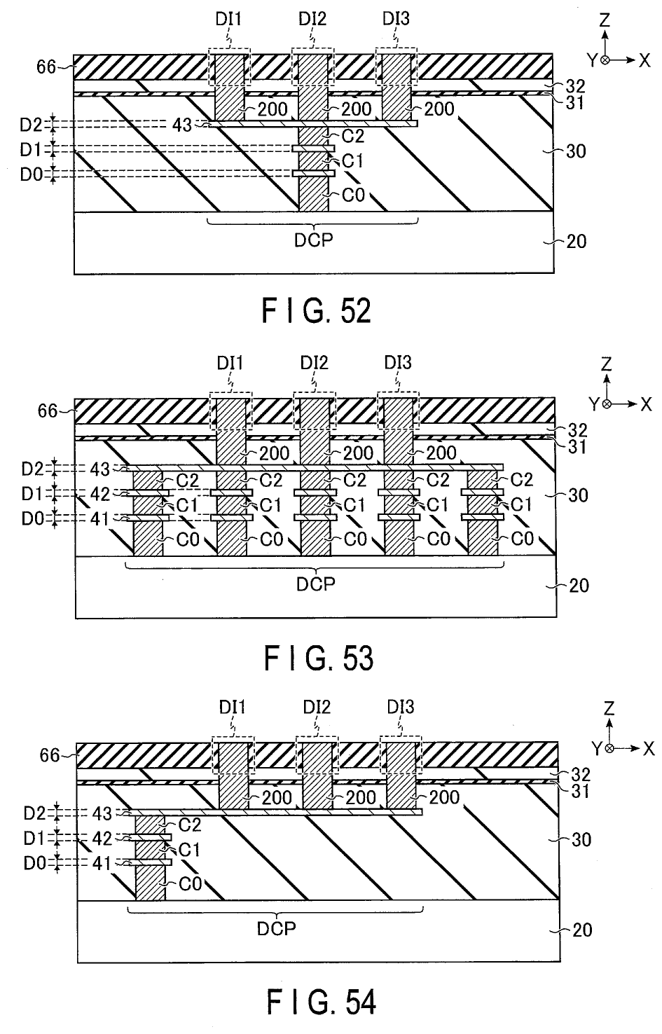

FIG. 52 is a cross-sectional view illustrating an example of cross-sectional structure of a discharge-path contact portion DCP in a semiconductor memory device 1 according to a second modification of the second embodiment. As illustrated in FIG. 52, in the second modification of the second embodiment, the number (for example, one) of contacts C0 connected to the semiconductor substrate 20 is less than the number of plugs (three plugs) 200 corresponding to the diode portions DI1, DI2 and DI3. In this manner, the number of plugs 200 connected to the conductive layers 60 and 62 may be greater than the number of contacts C0 connected to the semiconductor substrate 20.

In this case, circuits can be formed on the semiconductor substrate 20 and in each of the wiring layers D0 and DI so as to overlap portions where the diode portions DI1, DI2 and DI3 are formed. In other words, in the semiconductor memory device 1 according to the second modification of the second embodiment, the number of discharge paths of arcing can be made greater than in the second embodiment, and circuits can be disposed near the discharge-path contact portion DCP.

### [2-4-3] Third Modification of the Second Embodiment

FIG. 53 is a cross-sectional view illustrating an example of cross-sectional structure of a discharge-path contact portion DCP in a semiconductor memory device 1 according to a third modification of the second embodiment. As illustrated in FIG. 53, in the third modification of the second embodiment, the number (for example, five) of contacts C0 connected to the semiconductor substrate 20 is greater than the number of plugs (three plugs) 200 corresponding to the diode portions DI1, DI2 and DI3. In this manner, the number of plugs 200 connected to the conductive layers 60 and 62 may be less than the number of contacts C0 connected to the semiconductor substrate 20.

In this case, the number of current paths from the diode portions DIl, DI2 and DI3 to the semiconductor substrate 20 increases. Thereby, the semiconductor memory device 1 according to the third modification of the second embodiment can improve the discharge capability of the discharge-path contact portion DCP, and can more suppress the influence of arcing than in the second embodiment.

### [2-4-4] Fourth Modification of the Second Embodiment

FIG. 54 is a cross-sectional view illustrating an example of cross-sectional structure of a discharge-path contact portion DCP in a semiconductor memory device 1 according to a fourth modification of the second embodiment. As illustrated in FIG. 54, in the fourth modification of the second embodiment, the number (for example, one) of contacts C0 connected to the semiconductor substrate 20 is less than the number of plugs (three plugs) 200 corresponding to the diode portions DI1, DI2 and DI3. Furthermore, the contacts C0, C1 and C2 provided in lower layers than the wiring layer D2 are disposed in such a manner as not to overlap the diode portions DI1, DI2 and DI3. In this manner, in the discharge-path contact portion DCP, the contacts C0, C1 and C2 and the plug 200 may not be aligned in the Z direction.

In this case, the layout of transistors provided near the discharge-path contact portion DCP can be made easier. In other words, the semiconductor memory device 1 according to the fourth modification of the second embodiment can enhance the degree of freedom of the circuitry layout of the semiconductor substrate 20, and can reduce the chip area of the semiconductor memory device 1. Note that it suffices that, in the fourth modification of the second embodiment, the region of disposition of the contact C0 is displaced from the regions of disposition of the plugs 200. The number of contacts C0 and the number of plugs 200 may be equal, or the number of contacts C0 may be greater than the number of plugs 200.

### [3] Others

In the above embodiments, the number of sealing members ESn and ESp provided in the semiconductor memory device 1 is not limited to the number described in the embodiments. It suffices that the semiconductor memory device 1 includes at least one set of the sealing members ESn and ESp. Two or more sealing members ESn may be provided. A plurality of the sealing members ESn may be adjacent to each other. Two or more sealing members ESp may be provided. A plurality of the sealing members ESp may be adjacent to each other. The conductive layer 92 and the like may be shared between two or more sealing members ESn adjacent to each other. The conductive layer 92 and the like may be shared between two or more sealing members ESp adjacent to each other.

In addition, it suffices that each of the sealing members ESn and ESp has at least a square ring wall-like structure, and the numbers of contacts and conductive layers included in each of the sealing members ESn and ESp may be other numbers. As a material used as the conductive layer and the contact included in the sealing members ESn and ESp, use is made of, for example, a metallic material such as titanium, titanium nitride or tungsten. Aside from this, various metallic materials can be used for the sealing members ESn and ESp. As a measure against static electricity or the like from the outside, it is preferable that the sealing member ESn is disposed on the outermost periphery.

In the first embodiment, the dividing portion KC may not necessarily include the contact C3P. It suffices that the dividing portion KC insulates at least the conductive layers 62 and 60 in the memory region MA from the conductive layers 62 and 60 in the wall region WR. For example, in step S32, when the slit formed in the dividing portion KC is designed to be thinner than the slit formed in the wall region WR, the dividing portion KC may be composed of only an insulator.

In the above embodiments, the memory pillar MP may have such a structure that two or more memory pillars MP are connected together in the Z direction. In this case, the term “high aspect ratio etching process” used in the description of the present specification corresponds to the etching process of the hole corresponding to the pillar reaching the source line SL, or the like. Furthermore, the memory pillar MP may have such a structure that a pillar corresponding to the select gate line SGD and a pillar corresponding to the word line WL are connected together. The memory pillar MP and the bit line BL, the contact CC and the conductive layer 26, and the contact C3 and the conductive layer 27, may each be connected by a plurality of contacts which are connected together in the Z direction. A conductive layer may be inserted into a connecting portion of the plurality of contacts. This also applies to other contacts.

In the drawings used for the description in the above embodiments, the case was exemplified in which the memory pillar MP has the same diameter in the Z direction; however, the embodiments are not limited to this. For example, the memory pillar MP may have a tapered shape or a reverse tapered shape, or may have a shape in which the intermediate portion is bulged (bowing shape). Similarly, each of the slit SLT and SHE may have a tapered shape or a reverse tapered shape, or may have a bowing shape. Similarly, each of the contacts C0W, C1W, C2W, C3W, C3P, V0W, and V1W may have a tapered or reverse tapered shape, or may have a bowing shape. Furthermore, in the above embodiments, the case was exemplified in which the cross-sectional structures of the memory pillar MP and the contacts CC and C3 are circular; however, these cross-sectional structures may be elliptical and can be designed in any shape.

In the above embodiments, the inside of each of the slits SLT and SHE may include a single or a plurality of types of insulators. In this case, for example, a contact for the source line SL (conductive layer 21) is provided in, for example, the hookup region HA. In the present specification, a position of the slit SLT is specified based on, for example, a position of the contact LC. When the slit SLT is composed of an insulator, the position of the slit SLT may be specified by a seam in the slit SLT or a material remaining in the slit SLT during the replacement process.

Note that, as regards the “square ring” in the present specification, it suffices that a target constituent element is formed in a ring shape while including at least portions extending in directions intersecting with each other. Furthermore, the “square ring” may be formed to have a corner portion obliquely formed, and may include a portion in which a side is not foamed in a straight line. The “square ring” is preferably a perfect ring, but a part of the ring portion may be interrupted. If the sealing members ESn and ESp have substantially ring structures, the advantageous effects of the sealing members ESn and ESp described in the above embodiments can be obtained. The “ring” is not limited to a circle, but also includes a square ring. The “diameter” indicates the inside diameter of a hole or the like in a cross section parallel to the surface of the semiconductor substrate. The “width” indicates the width of a constituent element in, for example, the X direction or the Y direction. The “side walls” indicate one side surface portion and the other side surface portion of the slit.

In the present specification, the “connection” indicates a state of being electrically connected, and does not exclude, for example, a connection via another element. The term “electrically connected” may indicate a connection via an insulator, if the same operation as by electrical connection is possible. In addition, in the present specification, the term “connection” is also applicable to a part divided by the dividing portion KC. Specifically, when a first structure and a second structure are connected and a dividing portion is provided between the first structure and the second structure, the first structure and the second structure are insulated. The term “columnar” indicates being a structure which is provided in the hole formed in the manufacturing process of the semiconductor memory device 1. It suffices that the term “identical layer structure” means that at least the order of formation of layers is identical.

In the present specification, the “P-type well region” indicates a region of the semiconductor substrate 20 containing P-type impurities. The “N-type impurity diffusion region” indicates a region in which the semiconductor substrate 20 is doped with N-type impurities. The “P-type impurity diffusion region” indicates a region in which the semiconductor substrate 20 is doped with P-type impurities. The “semiconductor layer” may be referred to as “conductive layer”. The “PN-junction diode” may be referred to simply as “diode”.

In the present specification, the “region” may be regarded as a configuration included by the semiconductor substrate 20. For example, when the semiconductor substrate 20 is defined as including the memory region MA and the hookup region HA, the memory region MA and the hookup region HA are respectively associated with different regions above the semiconductor substrate 20. The “height” corresponds to, for example, a distance in the Z direction between a measurement target configuration and the semiconductor substrate 20. As a reference of the “height”, a configuration other than the semiconductor substrate 20 may be used. The “planar position” indicates a position of a structural element in a plan layout.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor memory device comprising:
a substrate;
a source line provided above the substrate;
a plurality of word lines provided above the source line, the word lines being spaced apart from each other in a first direction intersecting a surface of the substrate;
a pillar provided to extend in the first direction, a bottom portion of the pillar reaching the source line, and each of intersection portions between the pillar and the word lines functioning as a memory cell; and
a first contact portion provided on the substrate, the first contact portion being connected between the source line and the substrate, wherein
an inside of the first contact portion, or a portion in which a conductive layer included in the source line is in contact with the first contact portion, includes a portion functioning as a diode, the portion functioning as the diode being electrically connected in a reverse direction from the source line toward the substrate.

2. The device of claim 1, wherein
the first contact portion includes a first semiconductor layer on the substrate, and a second semiconductor layer on the first semiconductor layer,
the first semiconductor layer contains P-type impurities,
the second semiconductor layer contains N-type impurities, and
a set of the first semiconductor layer and the second semiconductor layer functions as the diode.

3. The device of claim 2, wherein
the first semiconductor layer is an epitaxial layer.

4. The device of claim 2, wherein
the first semiconductor layer is a polysilicon layer.

5. The device of claim 2, wherein
a P-type impurity concentration of the first semiconductor layer is in a range of 10¹⁴ to 10¹⁶ (atoms/cm³) , and
an N-type impurity concentration of the second semiconductor layer is 10²⁰ (atoms/cm³) or more.

6. The device of claim 1, wherein
the first contact portion includes:
a first contact on the substrate, the diode being included in an inside of the first contact;
a first wiring line on the first contact; and
a second contact above the first wiring line, the second contact being electrically connected between the first wiring line and the source line.

7. The device of claim 6, wherein
the source line and the substrate are electrically connected via one or more of the first contacts and one or more of the second contacts, and
a number of the first contacts and a number of the second contacts are different, the first and second contacts being used for connecting the source line and the substrate.

8. The device of claim 2, wherein
the first contact portion further includes a conductive member on the second semiconductor layer, a side surface of the conductive member being in contact with the source line.

9. The device of claim 1, wherein
the conductive layer included in the source line includes, as the portion functioning as the diode, a set of a semiconductor layer containing P-type impurities and a semiconductor layer containing N-type impurities, the semiconductor layer containing the P-type impurities being in contact with the first contact portion.

10. The device of claim 9, wherein
the first contact portion includes:
a first contact on the substrate;
a first wiring line on the first contact; and
a second contact above the first wiring line, the second contact being electrically connected between the first wiring line and the source line, and
a side surface of the second contact is in contact with the semiconductor layer containing the P-type impurities.

11. A semiconductor memory device comprising:
a substrate including a first core region, and a first region provided to surround an outer periphery of the first core region;
a first source line provided in a first layer above the substrate in the first core region;
a plurality of first word lines provided in the first core region and above the first source line, the first word lines being spaced apart from each other in a first direction intersecting a surface of the substrate;
a first pillar provided to extend in the first direction in the first core region, a bottom portion of the first pillar reaching the first source line, and each of intersection portions between the first pillar and the first word lines functioning as a memory cell;
an outer peripheral conductive layer included in the first layer in the first region and provided to surround the first core region; and
a first plug provided to divide a conductive layer included in the first source line and the outer peripheral conductive layer, the first plug being electrically connected between the first source line and the substrate, wherein
the conductive layer included in the first source line includes a first diode in a contact part with the first plug, the first diode being electrically connected in a reverse direction from the first source line toward the first plug.

12. The device of claim 11, wherein
the conductive layer included in the first source line includes a first semiconductor layer and a second semiconductor layer, the first semiconductor layer being in contact with the first plug, and the second semiconductor layer being provided between the first semiconductor layer and the first pillar,
the first semiconductor layer contains P-type impurities,
the second semiconductor layer contains N-type impurities, and
a set of the first semiconductor layer and the second semiconductor layer functions as the first diode.

13. The device of claim 12, wherein
the first plug is electrically connected between the outer peripheral conductive layer and the substrate,
the outer peripheral conductive layer includes a third semiconductor layer and a fourth semiconductor layer, the third semiconductor layer being in contact with the first plug, and the fourth semiconductor layer being provided apart from the first plug and being in contact with the third semiconductor layer,
the third semiconductor layer contains P-type impurities,
the fourth semiconductor layer contains N-type impurities, and
a set of the third semiconductor layer and the fourth semiconductor layer functions as a second diode.

14. The device of claim 13, wherein
a P-type impurity concentration of each of the first semiconductor layer and the third semiconductor layer is less than 10²⁰ (atoms/cm³) , and
an N-type impurity concentration of each of the second semiconductor layer and the fourth semiconductor layer is 10²⁰ (atoms/cm³) or more.

15. The device of claim 13, further comprising:
a second source line;
a plurality of second word lines;
a second pillar; and
a second plug, wherein
the substrate further includes a second core region which is different from the first core region, the second core region being surrounded by the first region,
the second source line is provided in the first layer above the substrate in the second core region,
the second word lines are provided in the second core region and above the second source line, the second word lines being spaced apart from each other in the first direction,
the second pillar is provided to extend in the first direction in the second core region, a bottom portion of the second pillar reaching the second source line, and each of intersection portions between the second pillar and the second word lines functioning as a memory cell,
the second plug is provided to divide the conductive layer included in the first source line and a conductive layer included in the second source line, the second plug being electrically connected between the first source line and the substrate and between the second source line and the substrate,
the conductive layer included in the first source line includes a third diode in a contact part with the second plug, the third diode being electrically connected in a reverse direction from the first source line toward the second plug, and
the conductive layer included in the second source line includes a fourth diode in a contact part with the second plug, the fourth diode being electrically connected in a reverse direction from the second source line toward the second plug.

16. The device of claim 11, wherein
a plurality of the first diodes are disposed in parallel at a position where the conductive layer included in the first source line and the outer peripheral conductive layer are divided.

17. The device of claim 16, wherein
the first plug is divided in association with the respective first diodes, and
the divided first plugs are independently electrically connected to the substrate.

18. The device of claim 16, further comprising:
at least one first contact provided on the substrate, the at least one first contact being electrically connected between the substrate and the first plug; and
a first wiring line electrically connected between the at least one first contact and the first plug, wherein
the first plug is divided in association with the respective first diodes, and
a number of the at least one first contact is less than a number of the divided first plugs.

19. The device of claim 16, further comprising:
a plurality of first contacts provided on the substrate, the first contacts being electrically connected between the substrate and the first plug; and
a first wiring line electrically connected between at least one of the first contacts and the first plug, wherein
the first plug is divided in association with the respective first diodes, and
a number of the first contacts is greater than a number of the divided first plugs.

20. The device of claim 11, further comprising:
at least one first contact provided on the substrate, the at least one first contact being electrically connected between the substrate and the first plug, wherein
a planar position of the at least one first contact is displaced from a planar position of the first plug.
